(19) United States
(12) Patent Application Publication
(10) Pub. No.: US 2018/0053874 A1
(43) Pub. Date: Feb. 22, 2018

(54) DILUTE NITRIDE DEVICES WITH ACTIVE GROUP IV SUBSTRATE AND CONTROLLED DOPANT DIFFUSION AT THE NUCLEATION LAYER-SUBSTRATE INTERFACE

(71) Applicant: Solar Junction Corporation, San Jose, CA (US)

(72) Inventors: Ferran Suarez, San Jose, CA (US); Ting Liu, San Jose, CA (US); Arsen Sukiasyan, Santa Clara, CA (US)

(21) Appl. No.: 15/660,471

(22) Filed: Jul. 26, 2017

Related U.S. Application Data
(60) Provisional application No. 62/377,239, filed on Aug. 19, 2016.

(51) Int. Cl. H01L 31/18; H01L 31/0735; H01L 31/0725

(52) U.S. Cl. CPC H01L 31/1852; H01L 31/1856; H01L 31/0725; H01L 31/0735; H01L 31/1844

(57) ABSTRACT

Semiconductor devices having an antimony-containing nucleation layer between a dilute nitride material and an underlying substrate are disclosed. Dilute nitride-containing multijunction solar cells incorporating (Al)InGaPSb/Bi nucleation layers exhibit high efficiency.

### FIELD

The present invention relates to semiconductor devices having an antimony-containing nucleation layer between a dilute nitride material and an underlying substrate. Dilute nitride-containing multijunction solar cells incorporating (Al)InGaPSb/Bi nucleation layers exhibit high efficiency.

### BACKGROUND

The deposition of epitaxial layers to provide III/V optoelectronic devices, such as multijunction solar cells and light-emitting diodes (LEDs), on group IV substrates is known. The electronic and optical properties of such devices are being studied extensively and the correlation between these properties and the characteristics of the substrate-epilayer interface is receiving great attention. The reason for the attention given to the substrate-epilayer interface is that the performance of these devices is determined, in part, by the quality of this interface.

When a III/V material such as GaAs is epitaxially deposited on a group IV substrate such as a Ge substrate, the formation of the appropriate atomic layer sequence of the group III and group V layers is not readily established. The group IV sites (Ge atoms) can bond to either group III or group V atoms. In practice, some regions of the group IV substrate will bond group III atoms and other substrate regions will bond group V atoms. The boundary regions between these different growth areas give rise to structural defects, such as anti-phase domains, which adversely affect the performance of the device.

To curtail some of these structural defects, group IV substrates are usually vicinal substrates with an off-cut angle ranging from 0° to 15°. These vicinal substrates provide terraces and step edges where the atoms can bond with different configurations, thus providing greater order in the growth process.

In devices such as, for example, solar cells having III/V alloys epitaxially deposited on a group IV substrate, it can be desirable to create part of the device itself in the group IV substrate by diffusing, for example, a group V species into the group IV substrate. As an example, for solar cells, if a group V element is diffused in a p-type Ge substrate, an n-type region is formed, giving rise to a p-n junction. This p-n junction becomes photo-active and can be part of a single or multijunction solar cell. However, when depositing the III/V compound at typical process temperatures (500° C. to 750° C.) on the Ge substrate, the group V element of the compound tends to diffuse, with little control, in the substrate thereby making the formation of a predictable p-n junction difficult. In cases involving Ge substrates with a pre-existing p-n junction, as can be the case in the hetero-integration of III-V optoelectronics on Ge, SiGe and SiC electronic circuits, the deposition of an overlying III/V compound can modify the doping profile of the pre-existing p-n junction resulting in suboptimal performance of the p-n junction and device. The doping level is a result of the competition between in-diffusion and dopant loss. Consequently, the electrical characteristics of the interface are not easily controllable. In such situations, it can become difficult, if not impossible, to achieve and maintain a desired doping profile and the electrical characteristics of the p-n junction at the substrate interface, with such electrical characteristics including, in the case of solar cells, the open circuit voltage (Voc). Furthermore, group IV atoms will diffuse from the substrate into the epitaxially deposited III/V layers. Hence, overlying layers within the initial 0.5 μm to 1 μm of the III/V layer sequence can become highly doped with the group IV element when the excessive diffusion of group IV atoms is not curtailed through the use of suitable nucleation conditions and materials. Group IV atoms such as Si and Ge are, at moderate concentrations, typically n-type dopants in III/V semiconductor material. However, due to their amphoteric nature these atoms can cause a large degree of compensation (combined incorporation of n- and p-type impurities) when incorporated at concentrations higher than 2×10¹⁸ cm⁻³, which can lead to a strong deterioration of electrical and optical properties of the host semiconductor layer.

In U.S. Pat. No. 6,380,601, Ermer discloses the deposition of InGaP on an n-doped interface layer of a p-type Ge substrate and subsequent deposition of a GaAs binary compound on the InGaP layer. The phosphorus of the InGaP layer tends to not diffuse into the Ge substrate as deeply as does the arsenic in the GaAs layer. Thus, phosphorus from the interfacial InGaP layer shapes the doping profile of the n-type layer of the p-type Ge substrate and consequently leads to better control of the electrical characteristics of the p-n junction formed in the Ge substrate. However, a problem with having a InGaP layer interfacing with the Ge substrate is that the morphology of devices prepared under typical epitaxial process conditions for these materials is not ideal and the defect density is often high. It appears that extreme nucleation conditions (temperature, deposition rate, group V overpressure) of the InGaP layer are required to obtain devices with suitable morphology and a low defect density.

Antimony and bismuth are believed to act as surfactants that promote smooth growth morphology of III-AsNV alloys. Antimony and bismuth can facilitate uniform incorporation of nitrogen, minimize the formation of nitrogen-related defects, and alter the alloy band gap that makes a wider range of band gaps accessible. Olson et al. (Olson et al., 2006 IEEE 4^{th} World Conference on Photovoltaic Energy Conversion) discloses that the incorporation of antimony into an InGaP top subcell not only increases the band gap, Eg and Voc, but also improves InGaP morphology, implicating smooth surface morphology and good device performance. Olson et al. does not disclose whether antimony or bismuth enhances or attenuates the drift of specific dopants during epitaxial deposition. In U.S. Pat. Nos. 7,872,252 and 8,125,958, Puetz et al. disclose an AlAs nucleation layer on a Ge substrate. The AlAs nucleation layer provides a means to shape the position of a p-n junction near the surface of the Ge substrate by controlling dopant diffusion near the III/V and Ge substrate interface. The present disclosure discloses test results showing that the AlAs as taught by Puetz et al. is incompatible with dilute nitride systems.

Dilute nitrides are a class of III-V alloy materials (alloys having one or more elements from Group III in the periodic table along with one or more elements from Group V in the periodic table) with small fractions (less, than 5 atomic percent, for example) of nitrogen. Dilute nitrides are of interest because they can be lattice-matched to different substrates, including GaAs and Ge. Although metamorphic structures for III-V multijunction photovoltaic cells can be used, lattice-matched dilute nitride structures are preferred due to band gap tunability and lattice constant matching, making dilute nitrides ideal for integration into multijunction photovoltaic cells with substantial efficiency improvements. Dilute nitrides have proven performance reliability and require less semiconductor material in manufacturing. The high efficiencies of dilute nitride photovoltaic cells make them attractive for terrestrial concentrating photovoltaic systems and for photovoltaic systems designed to operate in space. Significantly, thermal treatment is an essential and unique step in the fabrication of dilute nitride photovoltaic cells, which is not required for conventional semiconductors.

This disclosure presents evidence that not only is the AlAs nucleation layer, as taught by Puetz et al., unsuccessful in attenuating the diffusion of gallium into a Ge substrate, but the presence of the AlAs nucleation layer degraded the performance of the device (FIGS. 1-7). The results indicate that AlAs is incompatible with the dilute nitride system. FIG. 1 shows the structure disclosed by Puetz et al. in which an AlAs nucleation layer is disposed between a p-type Ge substrate and an overlying n-type InGaP buffer layer. Several test structures were fabricated with varying AlAs thicknesses—10 angstroms, 2.8 angstroms, and 1.4 angstroms. The test structures were fabricated by metal-organic chemical vapor deposition (MOCVD) at deposition temperatures ranging from 580° C. to 720° C. Practitioners skilled in the art can recognize that additional semiconductor layers can be present in order to create a functional optoelectronic device and these additional layers are not shown in detail, such as window and buffer layers. Furthermore, cap or contact layer(s), anti-reflection coating (ARC) layers and electrical contacts (also known as metal grids) can be formed on top of the structure, and buffer layer(s), the substrate or handle, and bottom contacts can be formed or present below the structure. By convention in the photovoltaic cell art, the term “front” refers to the exterior surface of the device that faces the radiation source, and the term “back” refers to the exterior surface that is away from the radiation source. As used in the figures and descriptions, “back” is synonymous with “bottom” and “front” is synonymous with “top.”

FIGS. 2 and 3 show transmission electron microscopy (TEM) images of one of the structures containing an n-type AlAs nucleation layer, showing an about 200 nm-thick InGaP layer overlying an about 10 angstrom-thick (or about 1 nm-thick) layer of AlAs, which overlies a p-type Ge substrate (FIG. 2). The TEM images also show smooth morphology of the various epitaxial layers (FIG. 3). FIGS. 4A and 4B show a TEM image and a cross-sectional transmission electron microscopy (XTEM) analysis of the above-mentioned structure, respectively, where the abundance of elements is measured from the back side of the device, and confirms the presence of aluminum and arsenic in a thin region as germanium concentration decreases and as indium, gallium and phosphorus concentrations increase. The XTEM analysis indicates that a thin layer of AlAs lies between the Ge substrate and the InGaP layer, as designed.

The test structures described in FIGS. 1-4B were evaluated for performance. The results are shown in FIGS. 5A-6 and are summarized in Table 1. The test structures were single junctions. To simulate thermal load during the growth of the rest of the solar cell in a multijunction structure and/or with post-growth thermal treatments, rapid thermal annealing (RTA) was used to simulate the corresponding thermal load. RTA can maintain the same thermal load using higher temperatures during shorter periods of time.

TABLE 1
Test results for structures including AlAs nucleation layers.

| Test structure | 5-1 | 5-2 | 5-3 | 5-4, 5-5 | 5-6, 5-7, 5-8 | 5-9, 5-10, 5-11 |
|---|---|---|---|---|---|---|
| AlAs layer Thickness | 0 | 0 | 10 | 10 | 2.8 | 1.4 |
| (angstroms) | | | | | | |
| Thermal treatment | No | Yes | No | Yes | Yes | Yes |
| RTA Temperature | 0 | 780 | 0 | 780 | 690-640 | 690-640 |
| (° C.) for 20 seconds | | | | | | |
| Voc (V) | 0.26 | 0.18 | 0.25 | 0.01-0.14 | 0.07 | 0.12-0.16 |
| Fill Factor | 0.67 | 0.57 | 0.60 | 0.27-0.29 | 0.30-0.35 | 0.39-0.44 |
| Jsc (mA/cm²) | 30.8 | 27.3 | 29.9 | 4.4-4.6 | 10.7-18.1 | 14.3-25.2 |
| Efficiency (%) | 3.9 | 2.1 | 4.4 | 0 | 0.3-0.4 | 0.7-1.7 |

The thin layer of AlAs significantly degrades the performance of all test structures that were exposed to a thermal treatment. Degradation in performance appears to correlate with increasing AlAs thickness. Test structure 5-1 does not have an AlAs layer and was not exposed to thermal treatment. Test structure 5-2 is identical to test structure 5-1, except that test structure 5-2 was exposed to thermal treatment, which decreased the open circuit voltage (Voc), fill factor, short circuit current (Jsc) and efficiency. An AlAs layer is present in test structures 5-3, 5-4, 5-5, 5-6, 5-7, 5-8, 5-9, 5-10, and 5-11; test structures 5-4, 5-5, 5-6, 5-7, 5-8, 5-9, 5-10, and 5-11, and except for test structure 5-3, were exposed to thermal treatment. With thermal treatment, the decreased Voc, fill factor, Jsc and efficiency correlated with increasing AlAs thickness. AlAs was not chosen or designed by Puetz et al. to withstand thermal treatments routinely used in fabricating dilute nitride devices. In general, a thermal treatment is defined as exposure to a temperature that can range from 600° C. to 900° C. for a duration from 5 seconds to 3 hours. In some cases, there are no limits for temperature and time. Table 2 summarizes typical thermal treatment parameters by deposition method or thermal annealing condition.

TABLE 2
Thermal treatment methods, temperatures and times.

| Method | MBE | MOCVD | RTA | Oven |
|---|---|---|---|---|
| Time | 2-3 hours | 0.5-1 hour | 0.1-10 minutes | Any duration |
| Temperature | 600° C.- | 630° C.- | 600° C.- | Any temperature |
| | 650° C. | 700° C. | 900° C. | |

Therefore, new nucleation layers that can survive thermal treatment used in typical dilute nitride epitaxial process conditions, which results in devices with acceptable, if not improved, optical and electrical interface properties, due to suitable morphology and a well-defined dopant diffusion profile at the III/V and Ge substrate interface are desired.

### SUMMARY

According to the present invention, semiconductor devices comprise a substrate, wherein the substrate comprises GaAs, (Si,Sn)Ge or Si; and a nucleation layer overlying the substrate, wherein the nucleation layer comprises a III-V alloy, wherein the group V element comprises Sb, Bi, or a combination thereof.

According to the present invention, multijunction photovoltaic cells comprise a substrate, wherein the substrate comprises GaAs, (Si,Sn)Ge or Si; and a nucleation layer overlying the substrate, wherein the nucleation layer comprises a III-V alloy, wherein the group V element comprises Sb, Bi, or a combination thereof.

According to the present invention, solar energy power systems comprise at least one multijunction photovoltaic cell according to the present invention.

According to the present invention, methods of fabricating a semiconductor device comprise growing a nucleation layer on a substrate, wherein the nucleation layer comprises a III-V alloy, wherein the group V element comprises Sb, Bi, or a combination thereof; and growing at least one semiconductor layer on the nucleation layer.

According to the present invention, semiconductor devices comprise semiconductor devices fabricated using methods according to the present invention.

### BRIEF DESCRIPTION OF THE DRAWINGS

Those skilled in the art will understand that the drawings described herein are for illustration purposes only. The drawings are not intended to limit the scope of the present disclosure.

FIG. 1 is a schematic of a device structure disclosed in the prior art.

FIGS. 2 and 3 show TEM images and schematics of a device manufactured according to the prior art.

FIG. 4A shows a TEM image and schematic of a device manufactured according to the prior art.

FIG. 4B shows XTEM analysis of a device manufactured according to prior art.

FIG. 5A are graphs showing the Jsc, Voc, FF and efficiency for a device having an InGaP layer overlying an active p-Ge substrate with and without a thermal treatment.

FIG. 5B are graphs showing the Jsc, Voc, FF and efficiency for a device having an InGaP layer and various thicknesses of an AlAs nucleation layer overlying an active p-Ge substrate with and without a thermal treatment.

FIG. 6 shows the wavelength-dependent efficiency for devices without an AlAs nucleation layer and with different thicknesses of an AlAs nucleation layer.

FIG. 7A shows a TEM image and a schematic of a device structure having an InGaP nucleation layer overlying a p-Ge substrate.

FIG. 7B shows a TEM image and a schematic of a device structure having an InGaPSb nucleation layer overlying a p-Ge substrate.

FIGS. 8-10 show the distribution of elements within a p-Ge substrate and an overlying InGaP or InGaPSb nucleation layer, with and without thermal treatment, as determined by secondary ion mass spectrometry (SIMS).

FIG. 11 is a graph showing the Jsc, Voc, FF and efficiency of active p-Ge substrates, with and without Sb in the InGaP nucleation layer, and without thermal treatment.

FIG. 12 is a graph showing the wavelength-dependent efficiency of active p-Ge substrates, with and without Sb in the InGaP nucleation layer, and without thermal treatment.

FIG. 13 is a graph showing the Jsc, Voc, FF and efficiency of active p-Ge substrates, which were exposed to thermal treatment, with and without Sb in the InGaP nucleation layer.

FIG. 14 is a graph showing the wavelength-dependent efficiency of active p-Ge substrates, which were exposed to thermal treatment, with and without Sb in the InGaP nucleation layer.

FIG. 15 is a schematic of a multijunction solar cell with an InGaP nucleation layer or with an InGaPSb nucleation layer.

FIG. 16 shows graphs showing the Jsc, Voc, FF and efficiency of a four-junction (4J) multijunction photovoltaic cell with an InGaP nucleation layer or with an InGaPSb nucleation layer.

FIG. 17 shows graphs showing the Jsc for each subcell of a 4J multijunction photovoltaic cell with an InGaP nucleation layer or with an InGaPSb nucleation layer.

FIG. 18 shows the efficiency of each subcell of a 4J multijunction photovoltaic cell with an InGaP nucleation layer or with an InGaPSb nucleation layer.

FIG. 19 shows graphs showing the Jsc, Voc, FF and efficiency of a 4J multijunction photovoltaic cell with an InGaP nucleation layer or with an InGaPSb nucleation layer.

FIG. 20 shows graphs showing the Jsc of each subcell of a 4J multijunction photovoltaic cell with an InGaP nucleation layer or with an InGaPSb nucleation layer.

FIG. 21 shows the efficiency of each subcell of a 4J multijunction photovoltaic cell with an InGaP nucleation layer or with an InGaPSb nucleation layer.

FIG. 22 are graphs showing the Jsc, Voc, FF and efficiency for 4J multijunction photovoltaic cells with an InGaP nucleation layer or with an InGaPSb nucleation layer.

FIG. 23 shows the Jsc for each subcell of a 4J multijunction solar cell with either an InGaP nucleation layer or an InGaPSb nucleation layer.

FIG. 24 shows the wavelength-dependent efficiency for each subcell of a 4J multijunction solar cell with either an InGaP nucleation layer or an InGaPSb nucleation layer.

FIG. 25 shows the efficiency as a function of irradiance wavelength for GaInNAsSb subcells having different band gaps from 0.82 eV to 1.24 eV.

FIG. 26 summarizes the composition and function of certain layers of a 4J multijunction photovoltaic cell.

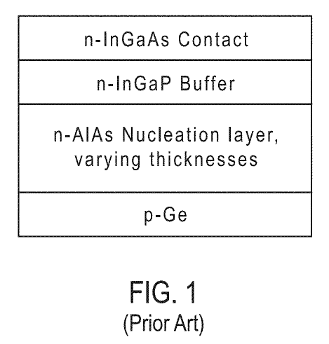

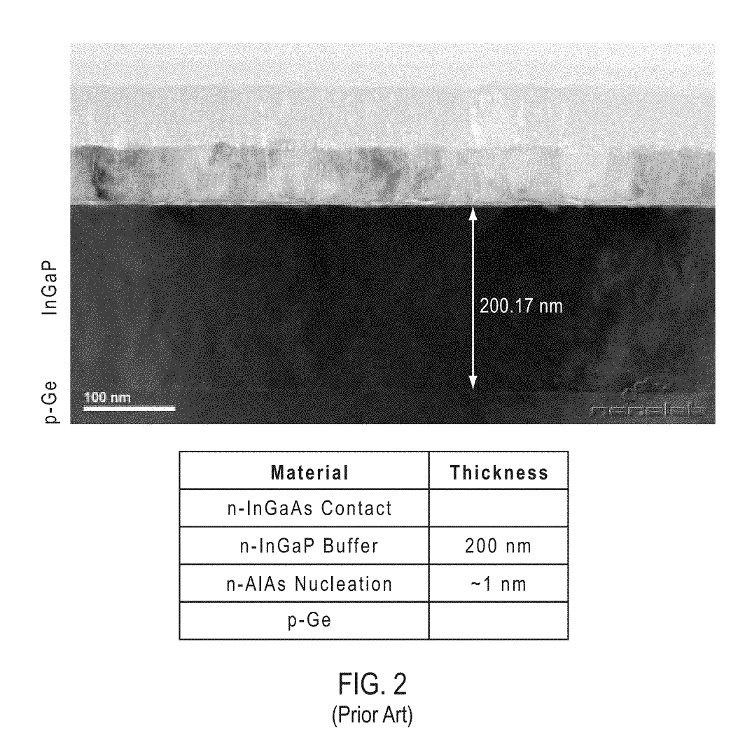

### DETAILED DESCRIPTION

The devices and methods of the present invention facilitate the manufacturing of high quality electronic and optoelectronic devices having a group IV substrate and an overlying dilute nitride structure. The disclosure teaches the manufacturing of devices with controlled doping profiles of group V elements into the group IV substrate, improved morphology, and high performance device characteristics. The use of nucleation layers containing Sb and/or Bi or other element that acts as a surfactant in the semiconductor alloy comprising the nucleation layer can render the semiconductor device more robust to thermal processing and in particular to thermal processing at high temperature. The use of nucleation layers containing Sb and/or Bi can modify, attenuate, and/or minimize the diffusion of elements from overlying semiconductor layers into an underlying layer such as, for example, a Ge substrate that would otherwise degrade the performance of the semiconductor device.

“(Al)InGaPSb/Bi” refers to a semiconductor alloy comprising InGaP and Sb, Bi, or both Sb and Bi. The semiconductor alloy may optionally include Al. For example, (Al)InGaPSb/Bi can include one or more of the semiconductor alloys InGaPSb, InGaPBi, InGaPSbBi, AlInGaPSb, AlInGaPBi, and AlInGaPSbBi. Similarly, InGaP(Sb) denotes that the alloy contains In, Ga, P, and optionally Sb.

“Lattice matched” refers to semiconductor layers for which the in-plane lattice constants of adjoining materials in their fully relaxed states differ by less than 0.6% when the materials are present in thicknesses greater than 100 nm. Further, subcells that are substantially lattice matched to each other means that all materials in the subcells that are present in thicknesses greater than 100 nm have in-plane lattice constants in their fully relaxed states that differ by less than 0.6%. In an alternative meaning, substantially lattice matched refers to the strain. As such, base layers can have a strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Strain refers to compressive strain and/or to tensile strain.

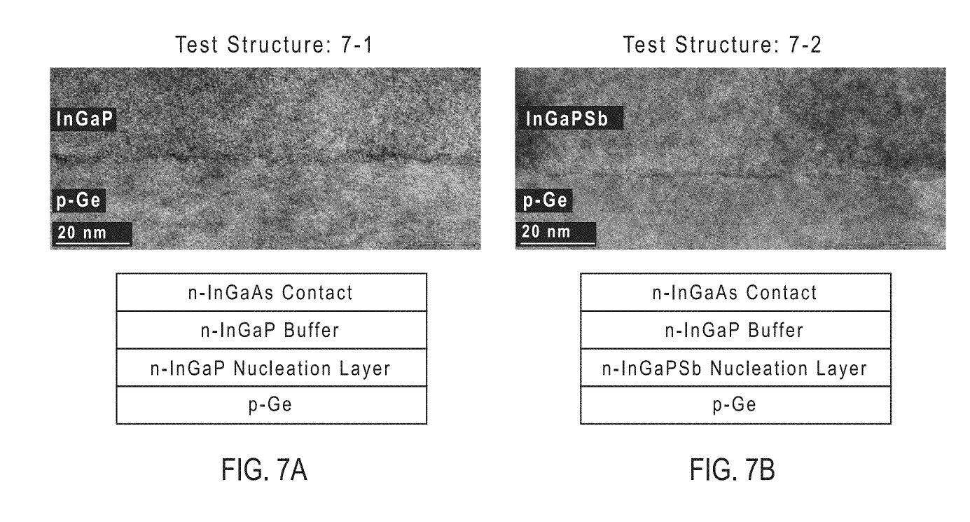

FIG. 7B shows a TEM image and a schematic of test structure 7-2, an embodiment of the invention, where a nucleation layer of n-type InGaPSb overlies an active p-Ge substrate.

InGaPSb can be used in multijunction photovoltaic cells and other optoelectronic devices, such as light-emitting diodes (LEDs). An n-InGaP buffer overlies the InGaPSb nucleation layer, and an n-InGaAs contact layer overlies the n-InGaP buffer layer. This structure can be compared to the conventional structure shown in FIG. 7A, test structure 7-1, which has an InGaP nucleation layer without antimony between the p-type Ge substrate and the overlying n-type InGaP buffer layer. TEM analysis shows that both structures were grown successfully without defects or dislocations at the interface between the p-Ge substrate and the nucleation layer. Smooth semiconductor morphology correlates with device performance and reliability.

To fabricate the test structures, a p-doped Ge substrate was first subjected to a thermal treatment in the growth reactor chamber to remove the oxide under V element overpressure. A thin 20 nm-thick InGaP nucleation layer or InGaPSb nucleation layer was deposited on the p-doped Ge substrate. A 200 nm-thick n-InGaP buffer layer was then grown on the nucleation layer under different conditions depending on the alloy used for the nucleation layer. For testing purposes, an InGaAs contact layer was grown on the n-InGaP buffer layer. All layers were lattice matched to the Ge substrate. To improve the morphology, a thin InGaP layer was nucleated on the Ge substrate before growing the InGaPSb layer. To simulate the thermal effects associated with dilute nitride processing such as the high-temperature thermal anneal, some of the devices were subjected to an RTA from 600° C. to 900° C. for a duration from 5 seconds to 3 hours.

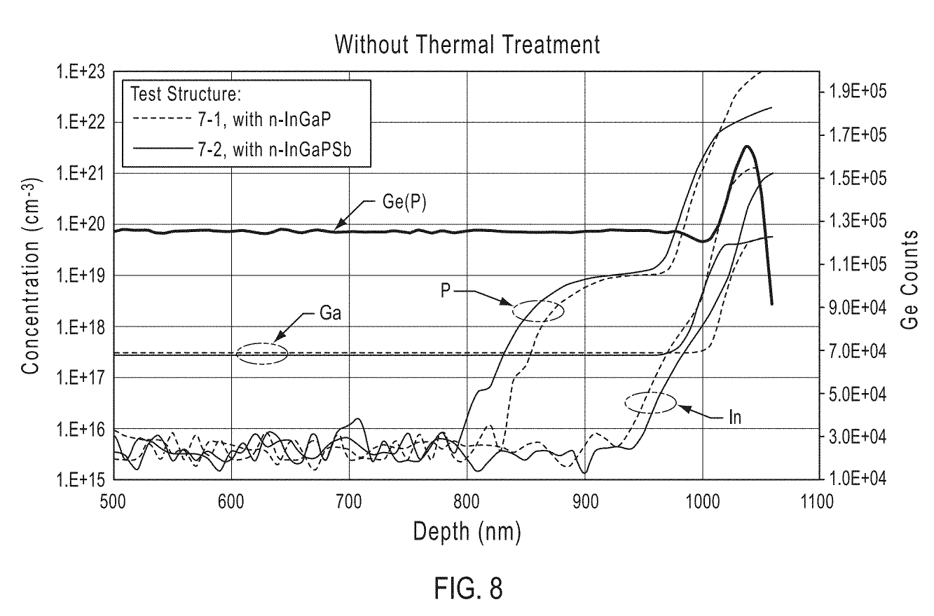

To compare the consequences of thermal treatment on the n-InGaP and n-InGaPSb nucleation layers, thermal treatment was applied to test structures 7-1 and 7-2. These test structures, with and without thermal treatment, were analyzed by secondary ion mass spectrometry (SIMS) to obtain information on varying elemental composition with respect to depth measured from the bottom surface of the device. SIMS involves removal of atoms from the semiconductor surface and is by nature a destructive technique. SIMS is suited for depth profiling applications and the method is applied to the bottom of the device at the start of the analysis, removing semiconductor material as the incident ion beam etches into the subcell. A device depth profile is thus obtained by recording sequential SIMS spectra as the surface is gradually removed. A plot of the intensity of a given mass signal as a function of depth is a direct reflection of the elemental abundance/concentration with respect to the vertical position below the top surface. FIGS. 8-10 show the results of this study.

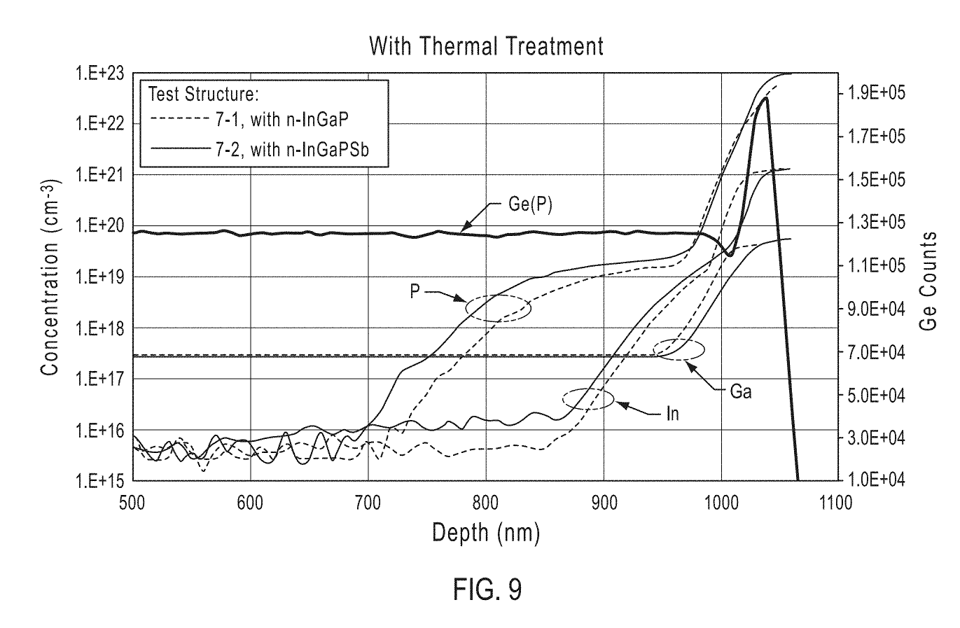

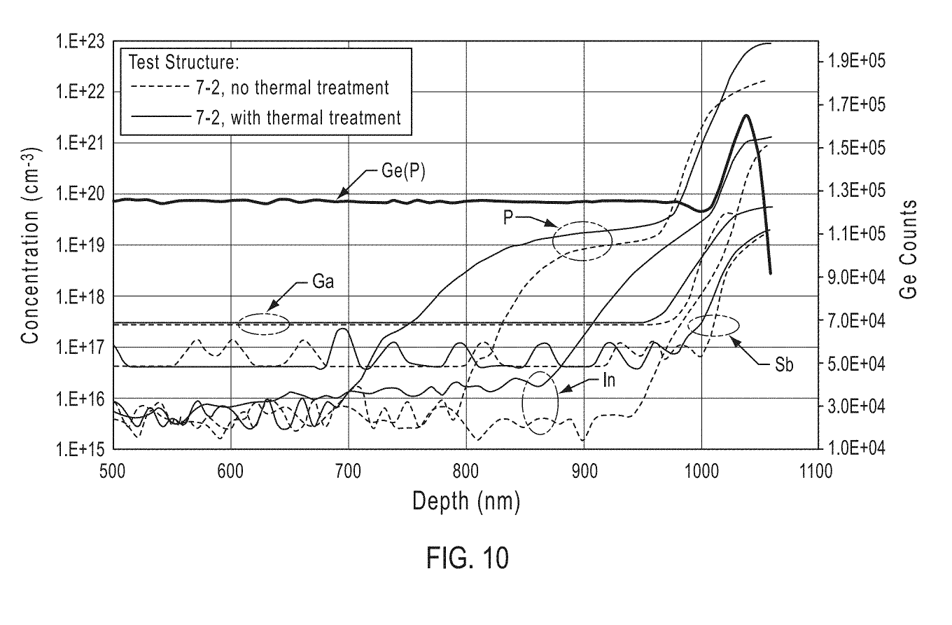

The depth-dependent elemental composition of test structures 7-1 and 7-2 (see FIG. 7A and FIG. 7B, respectively) prior to thermal treatment is compared in FIG. 8; and the depth-dependent elemental composition of test structures 7-1 and 7-2 after thermal treatment is compared in FIG. 9. Post thermal treatment, the elements phosphorous, indium and germanium to have migrated, as expected, from their original positions before thermal treatment. The presence of antimony from the n-InGaPSb nucleation layer was also detected where one expects to find the n-InGaPSb nucleation layer/p-Ge substrate interface (FIG. 10). Taken together, the SIMS analysis revealed that the presence of Sb in the n-InGaPSb nucleation layer of test structure 7-2 correlates with the attenuation of gallium migrating deeper into the p-Ge substrate (FIGS. 8 and 9). The presence of Sb in the n-InGaPSb nucleation layer appears to mitigates one of the consequences of the high-temperature thermal annealing, which is to further diffuse elements of overlying structures deeper into the p-Ge substrate (FIG. 10). A skilled practitioner in SIMS understands that sudden peaks, dips, shoulders or rollovers are routinely observed on the trailing edge of atomic concentration. For example, in FIGS. 8-10, a sudden dip in signal for germanium Ge, followed by a spike, is due to a buildup of Ge atoms caused by an abundance of material being etched away by the incident beam in previous layers. A buildup of elements (which are phosphorous P, indium In, gallium Ga, and antimony Sb, in test structures 7-1 and 7-2) competes with germanium Ge for the detector. Once the elemental buildup is removed, germanium Ge concentrations drop to expected levels. One skilled in the art can appreciate that germanium concentrations are low in layers overlying the p-germanium substrate, despite the otherwise apparent increased germanium concentration, due to this artifact.

In semiconductor devices provided by the present disclosure Sb may be present within the first 50 nm or within the first 25 nm of the top surface of the substrate from the interface with the nucleation layer. In semiconductor devices provided by the present disclosure increased gallium concentrations may be present within the first 50 nm, 40 nm, 30 nm, or 20 nm of the top surface of the substrate from the interface with the nucleation layer, and beneath this region have a constant doping profile, where the increased concentration of gallium near the interface with the nucleation layer is the result of diffusion of gallium from overlying layers into the substrate during processing.

As shown in FIG. 9, following thermal annealing Ga diffuses into the Ge substrate to a depth less than 50 nm, less than 40, nm, less than 30 nm, or less than 20 nm from the interface with the nucleation layer. The concentration of Ga decreases from about 1E19 atoms/cm³ to about 5E17 atoms/cm³. At depths greater than about 50 nm, the Ga concentration in the Ge substrate is constant at 5E17 atoms/cm³.

The attenuation of gallium diffusion due to the presence of antimony in the nucleation layer correlates with the preservation of high quality device performance. Various metrics can be used to characterize the quality of an optoelectronic device, including, for example, the Eg/q-Voc, the efficiency over a range of irradiance energies, the open circuit voltage, Voc, and the short circuit current density, Jsc. Those skilled in the art can understand how to extrapolate the Voc and Jsc measured for a subcell having a particular dilute nitride base thickness to other subcell thicknesses. The Jsc and the Voc are the maximum current density and voltage, respectively, for a photovoltaic cell. However, at both of these operating points, the power from the photovoltaic cell is zero. The fill factor (FF) is a parameter which, in conjunction with Jsc and Voc, determines the maximum power from a photovoltaic cell. The FF is defined as the ratio of the maximum power produced by the photovoltaic cell to the product of Voc and Jsc. Graphically, the FF is a measure of the “squareness” of the photovoltaic cell and is also the area of the largest rectangle, which will fit within the IV (current-voltage) curve.

Seemingly small improvements in the efficiency of a subcell can result in significant improvements in the efficiency of a multijunction photovoltaic cell. Again, seemingly small improvements in the overall efficiency of a multijunction photovoltaic cell can result in dramatic improvements in output power, reduce the area of a photovoltaic array, and reduce costs associated with installation, system integration, and deployment.

Photovoltaic cell efficiency is important as it directly affects the photovoltaic module power output. For example, assuming a 1 m² photovoltaic panel having an overall 24% conversion efficiency, if the efficiency of multijunction photovoltaic cells used in a module is increased by 1% such as from 40% to 41% under 500 suns, the module output power will increase by about 2.7 KW.

Generally a photovoltaic cell contributes around 20% to the total cost of a photovoltaic power module. Higher photovoltaic cell efficiency means more cost effective modules. Fewer photovoltaic devices are then needed to generate the same amount of output power, and higher output power with fewer devices leads to reduced system costs, such as costs for mounting racks, hardware, wiring for electrical connections, etc. In addition, by using high efficiency photovoltaic cells to generate the same power, less land area, fewer support structures, and lower labor costs are required for installation.

Photovoltaic modules are a significant component in spacecraft power systems. Lighter weight and smaller photovoltaic modules are always preferred because the lifting cost to launch satellites into orbit is expensive. Photovoltaic cell efficiency is especially important for space power applications to reduce the mass and fuel penalty due to large photovoltaic arrays. The higher specific power (watts generated over photovoltaic array mass), which determines how much power one array will generate for a given launch mass, can be achieved with more efficient photovoltaic cells because the size and weight of the photovoltaic array will be less for the same power output.

As an example, compared to a nominal photovoltaic cell having a 30% conversion efficiency, a 1.5% increase in multijunction photovoltaic cell efficiency can result in a 4.5% increase in output power, and a 3.5% increase in multijunction photovoltaic cell efficiency can result in an 11.5% increase in output power. For a satellite having a 60 kW power requirement, the use of higher efficiency subcells can result in photovoltaic cell module cost savings from $0.5 million to $1.5 million, and a reduction in photovoltaic array surface area of 6.4 m² to 15.6 m², for multijunction photovoltaic cells having increased efficiencies of 1.5% and 3.5%, respectively. The overall cost savings will be even greater when costs associated with system integration and launch are taken into consideration.

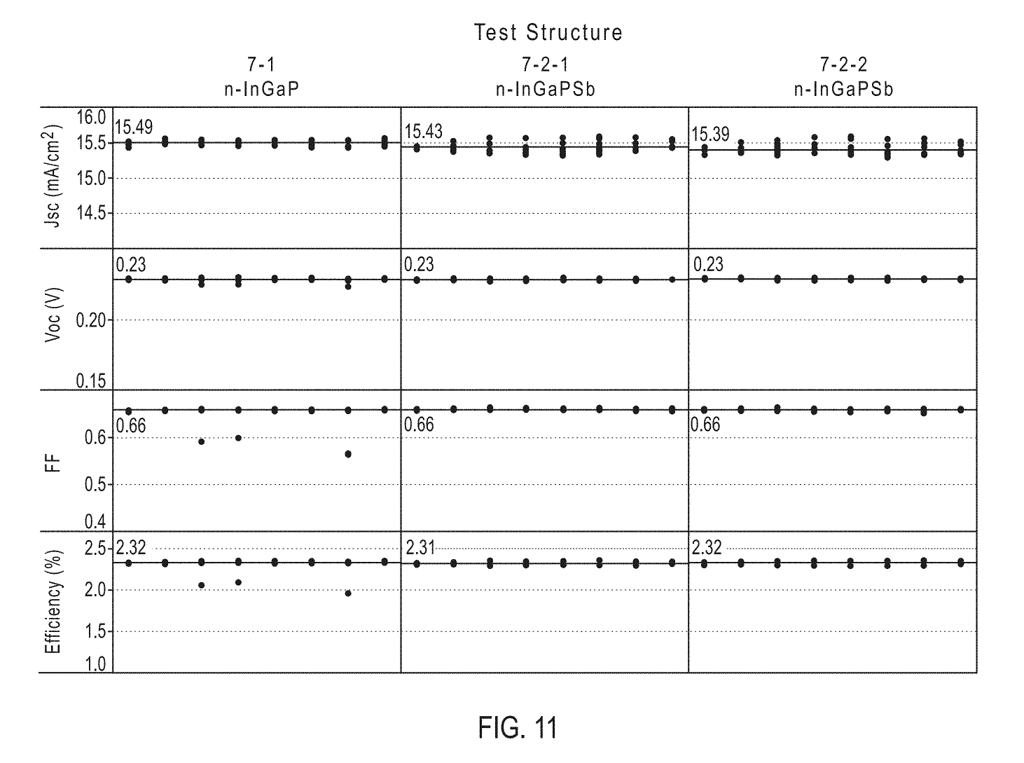

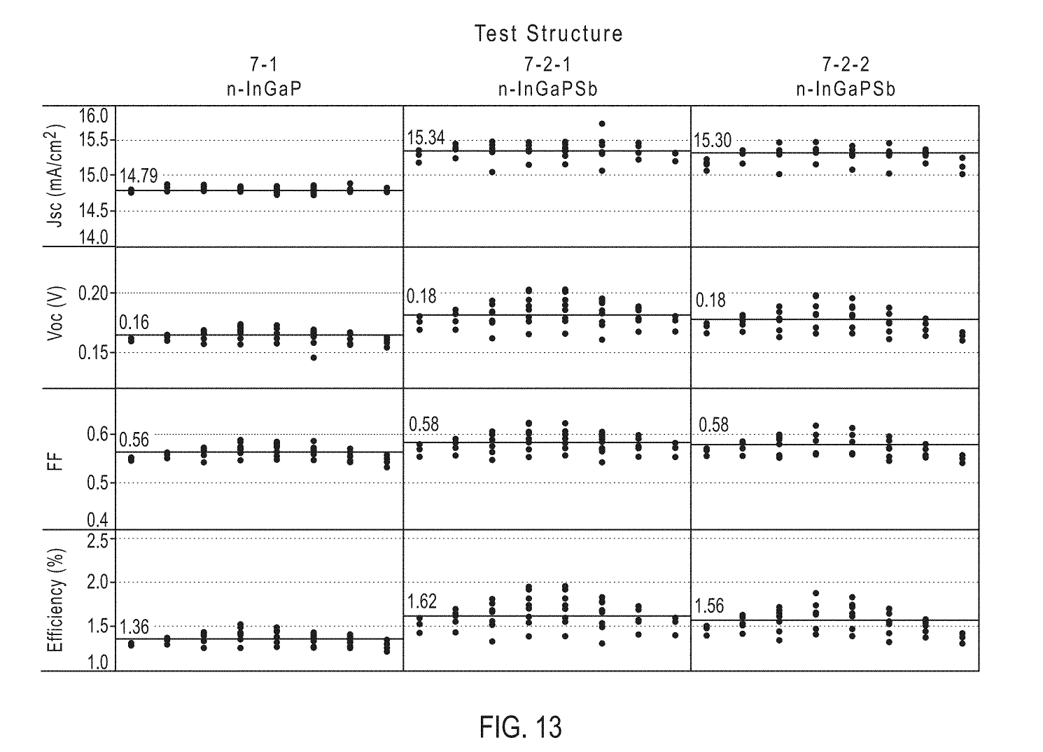

Preservation of high quality Jsc, Voc, and FF post-thermal treatment correlates with the presence of antimony in the nucleation layer. FIGS. 11 and 13 are graphs showing changes in Jsc, Voc, FF and efficiency of active p-Ge substrates. Data in FIG. 11 were measured before thermal treatment was applied and data in FIG. 13 were measured after thermal treatment was applied. Each device tested had a nucleation layer with InGaP or InGaPSb. Fifty individual 1-cm×1-cm photovoltaic cells on a 4-inch wafer were measured for each test structure. Device performance was measured at AM0. AM0 refers to the standard space spectrum at 1 sun and with device performance measured at a junction temperature of 25° C. The measurements are plotted according to the position of each cell along the y-dimension of the wafer. The results are summarized in Table 3.

TABLE 3
Effects of antimony in the nucleation layer on p-Ge
performance, with and without thermal treatment.

| Test structure | 7-1 | 7-1 | 7-2-1 | 7-2-1 | 7-2-2 | 7-2-2 |
|---|---|---|---|---|---|---|
| Nucleation layer | InGaP | InGaP | InGaPSb | InGaPSb | InGaPSb | InGaPSb |
| Thermal treatment | No | Yes | No | Yes | No | Yes |
| RTA 780° C. for | | | | | | |
| 20 sec | | | | | | |
| Voc (V) | 0.23 | 0.16 | 0.23 | 0.18 | 0.23 | 0.18 |
| Fill Factor | 0.66 | 0.56 | 0.66 | 0.58 | 0.66 | 0.58 |
| Jsc (mA/cm²) | 15.49 | 14.79 | 15.43 | 15.34 | 15.39 | 15.30 |
| Efficiency (%) | 2.32 | 1.36 | 2.31 | 1.62 | 2.32 | 1.56 |

With antimony present in the InGaP nucleation layer, devices that were exposed to a thermal treatment of 780° C. for 20 sec (RTA) had high performance values similar to devices that were not exposed to thermal treatment. Test structure 7-1 (without antimony) showed a decrease in Voc, FF, Jsc, and efficiency when exposed to thermal treatment. When comparing all test structures that were exposed to thermal treatment, structures 7-2-1 and 7-2-2 had values that surpassed the values of structure 7-1. Structures 7-2-1 and 7-2-2 had Voc, FF, Jsc and efficiency values that were comparable to values of test structure 7-1 prior to thermal treatment. The identifiers 7-1 and 7-2 refer to different epitaxial growth runs, and the identifier 7-2-1 and 7-2-2 refer to different wafers within a single epitaxial growth run. For each run, the growth conditions were nominally the same.

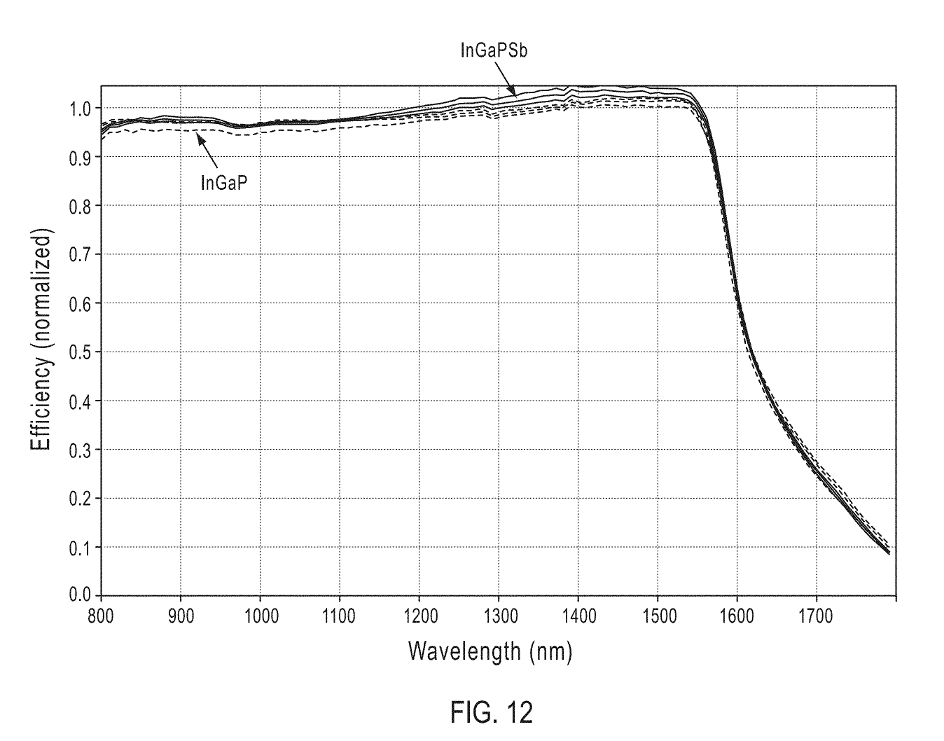

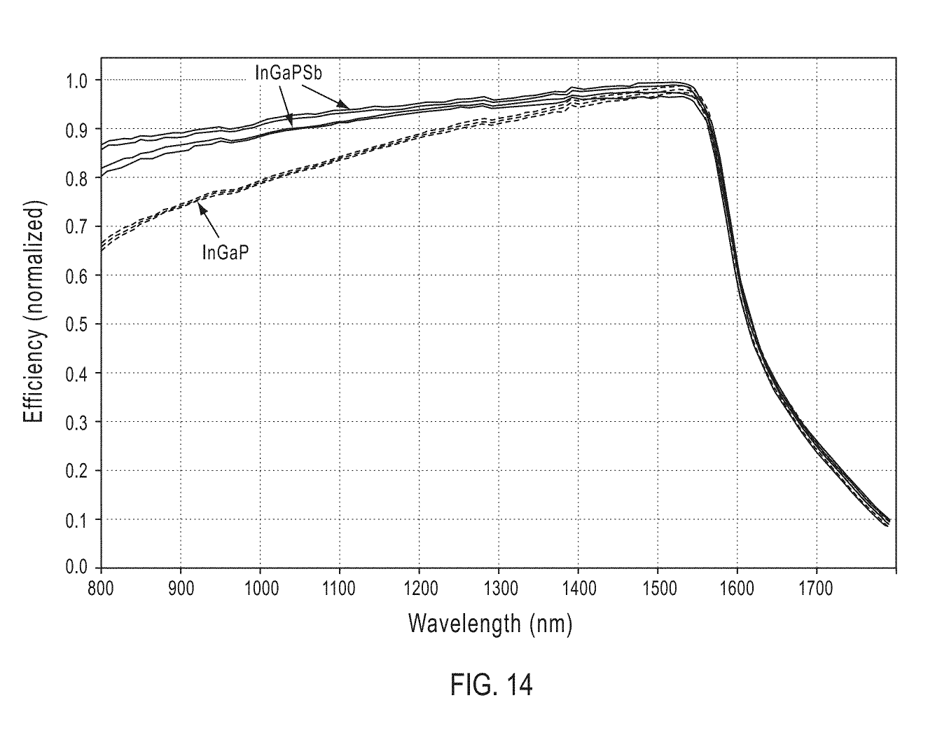

FIGS. 12 and 14 are graphs showing a comparison of the efficiency of an active p-Ge substrate over a range of irradiance energies. Devices with antimony in the nucleation layer (test structures 7-2-1 and 7-2-2) exhibited improved efficiencies especially following thermal treatment (FIG. 14) compared to devices having an InGaP nucleation layer. This observation was especially pronounced at irradiance wavelengths from 800 nm to 1400 nm.

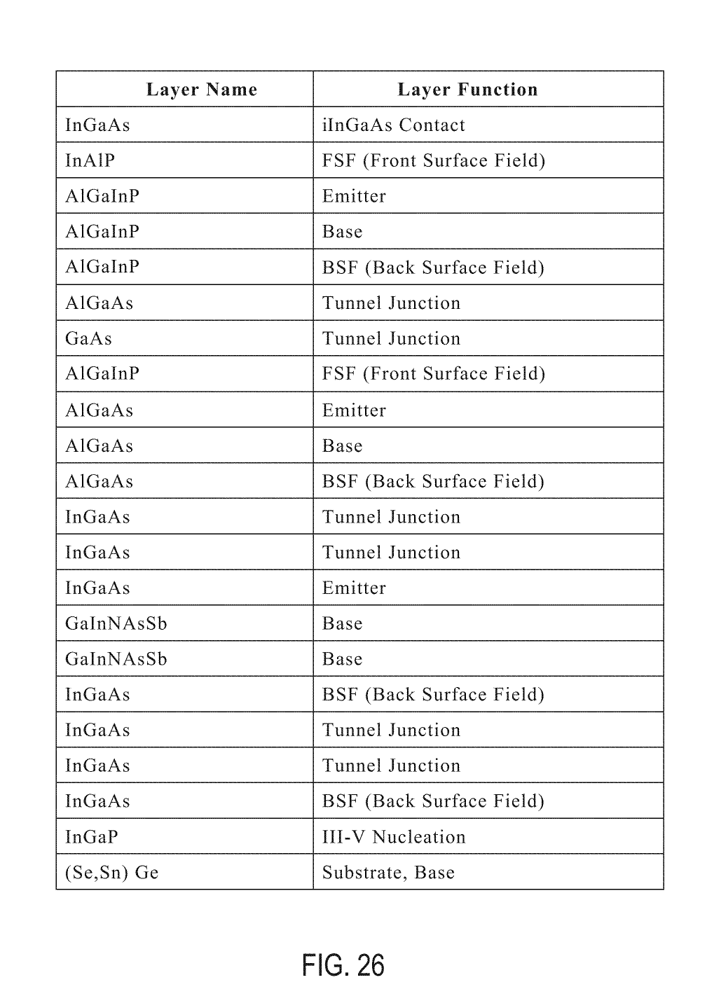

According to the invention, a (Al)InGaPSb/Bi nucleation layer with a p-Ge substrate can be incorporated into a dilute nitride multijunction photovoltaic cell. A practitioner skilled in the art understands that other types of layers may be incorporated or omitted in a photovoltaic cell to create a functional device and are not necessarily described here in detail. These other types of layers include, for example, coverglass, anti-reflection coating, contact layers, front surface field (FSF), tunnel junctions, window, emitter, back surface field (BSF), nucleation layers, buffer layers, and a substrate or wafer handle. In each of the embodiments described and illustrated herein, additional semiconductor layers can be present in order to create a photovoltaic cell device. Specifically, cap or contact layer(s), anti-reflection coating (ARC) layers and electrical contacts (also denoted as the metal grid) can be formed above the top subcell, and buffer layer(s), the substrate or handle, and bottom contacts can be formed or be present below the bottom subcell. In certain embodiments, the substrate may also function as the bottom subcell, such as in a germanium subcell. Multijunction photovoltaic cells may also be formed without one or more of the layers listed above, as known to those skilled in the art. Each of these layers requires careful design to ensure that its incorporation into a multijunction photovoltaic cell does not impair high performance. FIG. 26 shows an example 4J structure illustrating these possible additional semiconductor layers that may be present in a multijunction_photovoltaic cell.

Dilute nitrides are advantageous as photovoltaic cell materials in part because the lattice constant can be varied substantially to match a broad range of substrates and/or subcells formed from semiconductor materials other than dilute nitrides. Examples of dilute nitrides include GaInNAsSb, GaInNAsBi, GaInNAsSbBi, GaNAsSb, GaNAsBi and GaNAsSbBi. The lattice constant and band gap of a dilute nitride can be controlled by the relative fractions of the different group IIIA and group VA elements. Thus, by tailoring the compositions (i.e., the elements and quantities) of a dilute nitride material, a wide range of lattice constants and band gaps may be obtained. Further, high quality material may be obtained by adjusting the composition around a specific lattice constant and band gap, while limiting the total Sb and/or Bi content, for example, to no more than 20 percent of the Group V lattice sites, such as no more than 10 percent of the Group V lattice sites. Sb and Bi are believed to act as surfactants that promote smooth growth morphology of the III-AsNV dilute nitride alloys. In addition, Sb and Bi can facilitate uniform incorporation of N and minimize the formation of nitrogen-related defects. The incorporation of Sb and Bi can enhance the overall nitrogen incorporation and reduce the alloy band gap. However, Sb and Bi can also create additional defects and therefore it is desirable that the total concentration of Sb and/or Bi should be limited to no more than 20 percent of the Group V lattice sites. Further, the limit to the Sb and Bi content decreases with decreasing nitrogen content. Alloys that include In can have even lower limits to the total content because In can reduce the amount of Sb needed to tailor the lattice constant. For alloys that include In, the total Sb and/or Bi content may be limited to no more than 5 percent of the Group V lattice sites, in certain embodiments, to no more than 1.5 percent of the Group V lattice sites, and in certain embodiments, to no more than 0.2 percent of the Group V lattice sites. For example, Ga₁₋ₓInₓN_{y}As_{1-y-z}Sb_{z}, disclosed in U.S. Application Publication No. 2010/0319764, which is incorporated by reference in its entirety, can produce a high quality Ga₁₋ₓInₓN_{y}As_{1-y-z}Sb_{z} material when substantially lattice-matched to a GaAs or a Ge substrate in the composition range of 0.08≦x≦0.18, 0.025≦y≦0.04 and 0.001≦z≦0.03, with a band gap of at least 0.9 eV such as within a range from 0.9 eV to 1.25 eV. Ga₁₋ₓInₓN_{y}As_{1-y-z}Sb_{z} alloys suitable for use in high-efficiency 4J photovoltaic cells are disclosed in U.S. Application Publication No. 2017/0110613, which is incorporated by reference in its entirety. Ga₁₋ₓInₓN_{y}As_{1-y-z}Sb_{z} and Ga₁₋ₓInₓN_{y}As_{1-y-z1-z2}Sb_{z1}Bi_{z2} alloys suitable for use in high-efficiency multijunction photovoltaic cells are disclosed in U.S. application Ser. No. 15/609,760 filed on May 31, 2017, which is incorporated by reference in its entirety.

In dilute nitrides provided by the present disclosure, the N composition may not be more than 5.5 percent of the Group V lattice sites. In certain embodiments, the N composition is not more than 4 percent, and in certain embodiments, not more than 3.5 percent.

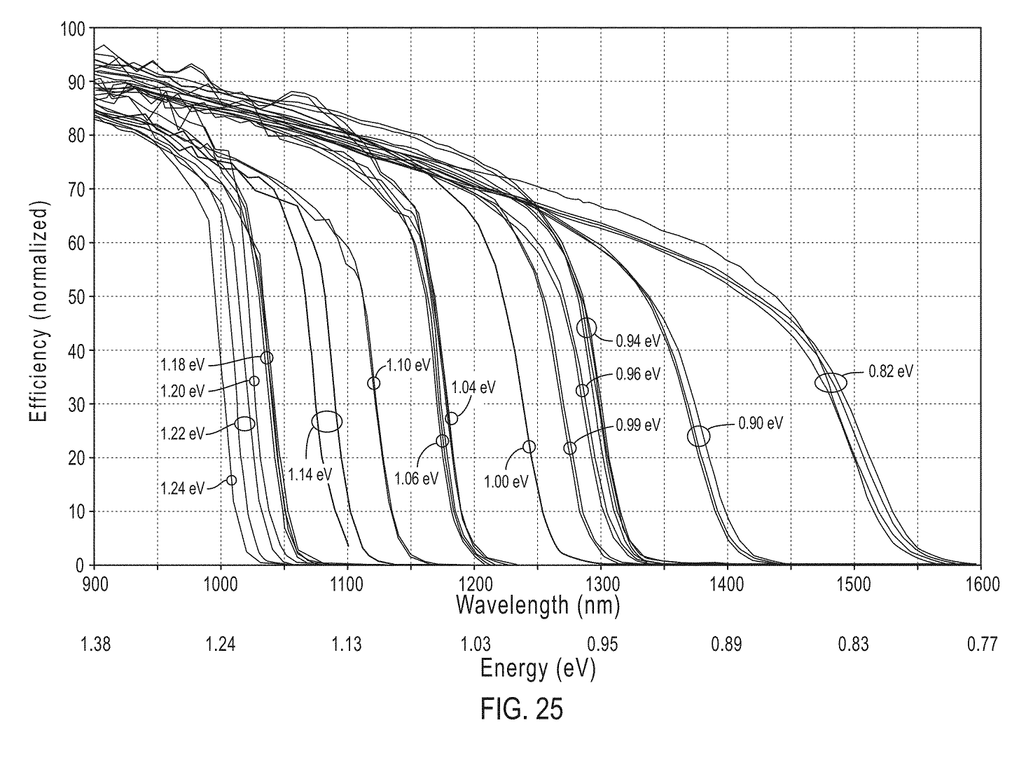

Embodiments of the present disclosure include dilute nitride subcells, comprising GaInNAsSb, GaInNAsBi, or GaInNAsBiSb in the base layer that can be incorporated into multijunction photovoltaic cells that perform at high efficiencies. As shown in FIG. 25, the efficiency of a dilute nitride subcell can vary depending on the bandgap and upon the irradiation energy/wavelength as well as on semiconductor properties such as the open circuit voltage Voc, short circuit current density Jsc, fill factor FF, defect density, doping profile, thickness, and other semiconductor solid state physics properties.

The band gaps of the dilute nitrides can be tailored by varying the composition while controlling the overall content of Sb and/or Bi. Thus, a dilute nitride subcell with a band gap suitable for integrating with other subcells may be fabricated while maintaining substantial lattice-matching to each of the other subcells and to the substrate. The band gaps and compositions can be tailored so that the Jsc produced by the dilute nitride subcells will be the same as or slightly greater than the Jsc of each of the other subcells in the photovoltaic cell. Because dilute nitrides provide high quality, lattice-matched and band gap-tunable subcells, photovoltaic cells comprising dilute nitride subcells can achieve high conversion efficiencies. The increase in efficiency is largely due to less light energy being lost as heat, as the additional subcells allow more of the incident photons to be absorbed by semiconductor materials with band gaps closer to the energy of the incident photons. In addition, there will be lower series resistance losses in these multijunction photovoltaic cells compared to other photovoltaic cells due to the lower operating currents. At higher concentrations of sunlight, the reduced series resistance losses become more pronounced. Depending on the band gap of the bottom subcell, the collection of a wider range of photons in the solar spectrum may also contribute to the increased efficiency.

Due to interactions between the different elements, as well as factors such as the strain in the dilute nitride layer, the relationship between composition and band gap for Ga₁₋ₓInₓN_{y}As_{1-y-z}Sb_{z}, Ga₁₋ₓInₓN_{y}As_{1-y-z}Sb_{z} and Ga₁₋ₓInₓN_{y}As_{1-y-z1-z2}Sb_{z1}Bi_{z2} is not a simple function of the elemental composition. The composition that yields a desired band gap with a specific lattice constant can be found by empirically varying the composition. However, the quality of the Ga₁₋ₓInₓN_{y}As_{1-y-z}Sb_{z}, Ga₁₋ₓInₓN_{y}As_{1-y-z}Sb_{z} and Ga₁₋ₓInₓN_{y}As_{1-y-z1-z2}Sb_{z1}Bi_{z2} alloys as reflected in attributes such as the Jsc, Voc, FF, and efficiency can depend on processing and annealing conditions and parameters.

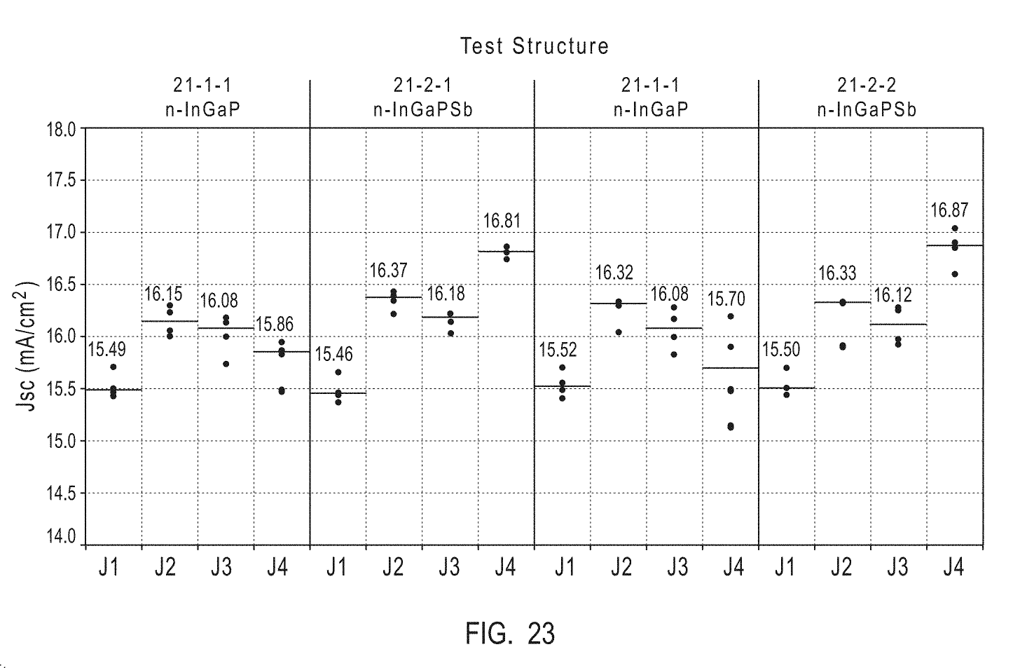

In some embodiments, a GaInNAsSb base can comprise Ga₁₋ₓInₓN_{y}As_{1-y-z}Sb_{z} having values for x, y, and z of 0.03≦x≦0.19, 0.008≦y≦0.055, and 0.001≦z≦0.05, and a band gap within the range from 0.9 to 1.25 eV. In some embodiments, a GaInNAsSb base can have a composition of Ga₁₋ₓInₓN_{y}As_{1-y-z}Sb_{z} having values for x, y, and z of 0.06≦x≦0.09, 0.01≦y≦0.03, and 0.003≦z≦0.02, and can have a band gap within the range from 1 eV to 1.16 eV. In some embodiments, a GaInNAsSb base can have a composition of Ga₁₋ₓInₓN_{y}As_{1-y-z}Sb_{z} having values for x, y, and z of 0.12≦x≦0.14, 0.025≦y≦0.035, and 0.005≦z≦0.015, and can have a band gap of around 0.96 eV. In some embodiments, a GaInNAsSb subcell can have a composition of Ga₁₋ₓInₓN_{y}As_{1-y-z}Sb_{z} having values for x, y, and z of 0.11≦x≦0.15, 0.025≦y≦0.04, and 0.003≦z≦0.015, and can have a band gap within the range from 0.95 eV to 0.98 eV. In some embodiments, a GaInNAsSb subcell can be characterized by a Eg/q-Voc equal to or greater than 0.55 V measured using a 1 sun AM1.5D spectrum at a junction temperature of 25° C. In some embodiments, a GaInNAsSb subcell can be characterized by an Eg/q-Voc from 0.4 V to 0.7 V measured using a 1 sun AM1.5D spectrum at a junction temperature of 25° C. The Ga₁₋ₓInₓN_{y}As_{1-y-z}Sb_{z} subcells characterized by the alloy compositions and band gaps disclosed in this paragraph can exhibit the efficiencies presented in FIG. 23. These Ga₁₋ₓInₓN_{y}As_{1-y-z}Sb_{z} subcells can exhibit high efficiency of greater than 70% and/or greater than 80% over a range of irradiation energies.

In some embodiments, a GaInNAsBi base can comprise Ga₁₋ₓInₓN_{y}As_{1-y-z}Sb_{z} having values for x, y, and z of 0.03≦x≦0.19, 0.008≦y≦0.055, and 0.001≦z≦0.015, and can have a band gap within a range from 0.9 to 1.25 eV. In some embodiments, a GaInNAsBi base can comprise Ga₁₋ₓInₓN_{y}As_{1-y-z}Sb_{z} having values for x, y and z of 0.06≦x≦0.09, 0.01≦y≦0.03, and 0.001≦z≦0.002, and can have a band gap within a range from 1 eV to 1.16 eV. In some embodiments, a GaInNAsBi base can comprise of Ga₁₋ₓInₓN_{y}As_{1-y-z}Sb_{z} having values for x, y and z of 0.12≦x≦0.14, 0.025≦y≦0.035, and 0.001≦z≦0.005, and can have a band gap of about 0.96 eV. In some embodiments, a GaInNAsBi base can comprise Ga₁₋ₓInₓN_{y}As_{1-y-z}Bi_{z} having values for x, y and z of 0.11≦x≦0.15, 0.025≦y≦0.04, and 0.001≦z≦0.005, and can have a band gap within a range from 0.95 eV to 0.98 eV.

In some embodiments, a GaInNAsSbBi base can comprise Ga₁₋ₓInₓN_{y}As_{1-y-z1-z2}Sb_{z1}Bi_{z2} having values for x, y, z1, and z2 of 0.03≦x≦0.19, 0.008≦y≦0.055, and 0.001≦z1+z2≦0.05, and can have a band gap within a range from 0.9 to 1.25 eV. In some embodiments, a GaInNAsSbBi base can comprise Ga₁₋ₓInₓN_{y}As_{1-y-z}Sb_{z} having values for x, y, z1, and z2 of 0.06≦x≦0.09, 0.01≦y≦0.03, and 0.001≦z1+z2≦0.02; and can have a band gap within a range from 1 eV to 1.16 eV. In some embodiments, a GaInNAsSbBi base can comprise Ga₁₋ₓInₓN_{y}As_{1-y-z}Sb_{z1}Bi_{z2} having values for x, y, z1, and z2 of 0.12≦x≦0.14, 0.025≦y≦0.035, and 0.001≦z1+z2≦0.015, and can have a band gap of about 0.96 eV. In some embodiments, a GaInNAsSbBi base can comprise Ga₁₋ₓInₓN_{y}As_{1-y-z1-z2}Sb_{z1}Bi_{z2} having values for x, y, z1, and z2 of 0.11≦x≦0.15, 0.025≦y≦0.04, and 0.001≦z1+z2≦0.015, and can have a band gap within a range from 0.95 eV to 0.98 eV.

In certain embodiments, the indium content is absent in the dilute nitride composition. In some embodiments, GaNAsBi is composed of GaN_{y}As_{1-y-z}Bi_{z}, where the content values for y, and z are within composition ranges as follows: 0.001≦y≦0.055, and 0.001≦z≦0.09. In some embodiments, GaNAsSbBi is composed of GaN_{y}As_{1-y-z1-z2}Sb_{z1}Bi_{z2}, where the content values for y, and z are within composition ranges as follows: 0.001≦y≦0.055, and 0.001≦z1+z2≦0.09.

A Sb and/or Bi-containing nucleation layer provided by the present disclosure can comprise (Al)InGaPSb/Bi such as InGaPSb, InGaPBi, InGaPSbBi, AlInGaPSb, AlInGaPBi, and AlInGaPSbBi. The alloy composition of the Sb and/or Bi-containing nucleation layer can be selected to be lattice matched to the Ge substrate. A Sb and/or Bi-containing nucleation layer can have a thickness, for example, less than 10 nm, less than 5 nm, 1 nm, less than 0.75 nm, less than 0.5 nm, or less than 0.25 nm. A Sb and/or Bi-containing nucleation layer can have a thickness, for example, from 0.01 nm to 10 nm, from 0.05 nm to 5 nm, or from 0.1 nm to 1 nm.

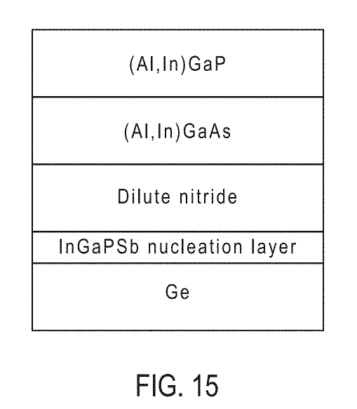

In some embodiments of the invention, the (Al)InGaPSb/Bi nucleation layer with a p-Ge substrate is incorporated into a four junction (4J) dilute nitride photovoltaic cell (FIG. 15). Except for (Al)InGaPSb/Bi, the materials shown in FIG. 15 indicate base layer materials. Each of the base layers is lattice matched to each of the other base layers and to the germanium or gallium arsenide substrate. P-Ge is an active substrate and forms the bottom-most subcell. An (Al)InGaPSb/Bi nucleation layer overlies p-Ge. The third (J3), second (J2) and first (J1) subcells above the nucleation layer have base layer materials that comprise a dilute nitride such as GaInNAsSb/Bi, (Al,In)GaAs and (A1,In)GaP, respectively. Practitioners skilled in the art can understand where an (Al)InGaPSb/Bi nucleation layer needs to be incorporated within the structure of a multijunction photovoltaic cell; thus a detailed description is not included here.

The properties of various test structures with a InGaP or InGaPSb nucleation layer were determined with different thermal loads. For example, when growing a 4J multijunction solar cell, it is estimated that during growth of the top two subcells, J1 and J2, the bottom layers, J3 and J4, are exposed to a temperature of about 620° C. for about 3 hours. In addition, test structures were exposed to a rapid thermal anneal of 765° C. for 20 seconds after growth of all layers.

In the 4J structure shown in FIG. 15, the J4 bottom subcell can be a p- or n-type Ge substrate that can be doped from 5E17 atoms/cm³ to 1E18 atoms/cm³. Phosphorous diffusing from an overlying layer can produce an n-type region in the Ge substrate with a doping density near the interface from about 5E17 atoms/cm³ to 1E19 atoms/cm³. J3 comprises a dilute nitride material and can be, for example, from 1 μm to 4 μm thick. The J3 junction can be configured as a p-n or p-i-n junction to improve carrier collection. The base doping can be in the range from 1E16 atoms/cm³ to 1E18 atoms/cm³ and the emitter can have a doping of about 1E18 atoms/cm³. The bandgap of J3 can be, for example, from 0.9 eV to 1.2 eV, such as from 0.9 eV, to 1.1 eV, or from 0.9 eV to 1.0 eV. J2 can comprise (Al,In)GaAs with from about 0 mol % to 10 mol % Al, and a bandgap from about 1.4 eV to about 1.5 EV. J2 can have a thickness, for example, from 1 μm to 4 μm and can have a doping density from about 1E16 atoms/cm³ to 1E18 atoms/cm³. J1, the top subcell, can comprise (Al,In)GaP with from 0 mol % to 5 mol % Al and a bandgap from 1.88 eV to 2 eV. J1 can have a thickness from 1 μm to 2 μm and a doping density from 1E16 atoms/cm³ to 1E18 atoms/cm³. Each junction comprises a FSF and BSF layer and the junctions are separated by tunnel junctions. The doping profiles for each subcell can be constant, gradual or exponential over all or over a portion of the subcell thickness

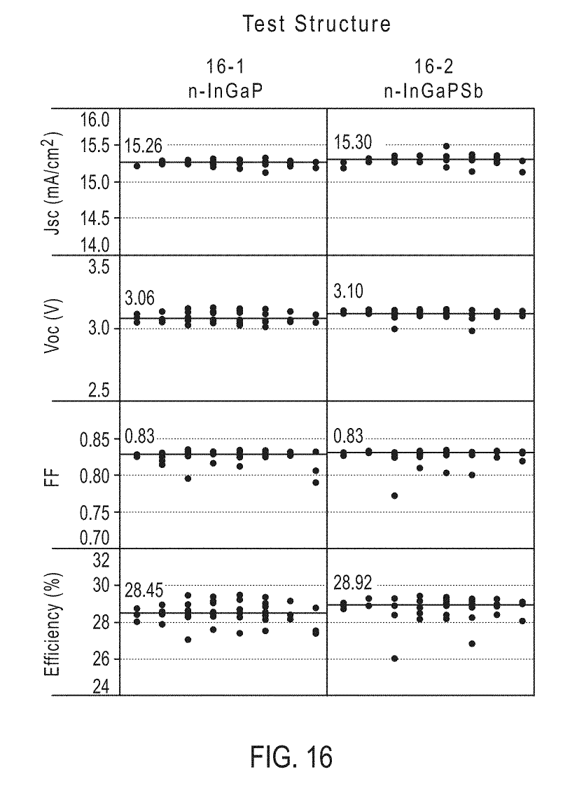

Performance attributes for the 4J structure shown in FIG. 15 with either an InGaP or InGaPSb nucleation layer are shown in FIGS. 16-18. Test structure 16-1 contains an InGaP nucleation layer and test structure 16-2 contains an InGaPSb nucleation layer. The bottom cell structure including the dilute nitride, nucleation layer and Ge substrate were subjected to a thermal load of about 620° C. during the 3-hour growth of the rest of the multijunction solar cell. For the test structure of FIG. 15, a typical InGaPSb nucleation layer is lattice matched to Ge and has the composition In_{0.5}Ga0.5P_{1.0}Sb_{0.02-0.04}.

In FIG. 16, the Jsc, Voc, FF, and efficiency of the multijunction photovoltaic cells having the structure shown in FIG. 15 with an n-InGaP nucleation layer (test structure 16-1) and with an n-InGaPSb nucleation layer (test structure 16-2) are compared. The Voc (+40 meV) and FF (+0.2%) are higher for test structure 16-2 compared to that for test structure 16-1. Fifty-five (55) individual 1-cm×1-cm photovoltaic cells on a 4-inch wafer were measured for each test structure. Device performance was measured at AM0. The measurements are plotted according to the position of each cell along the y-dimension of the wafer.

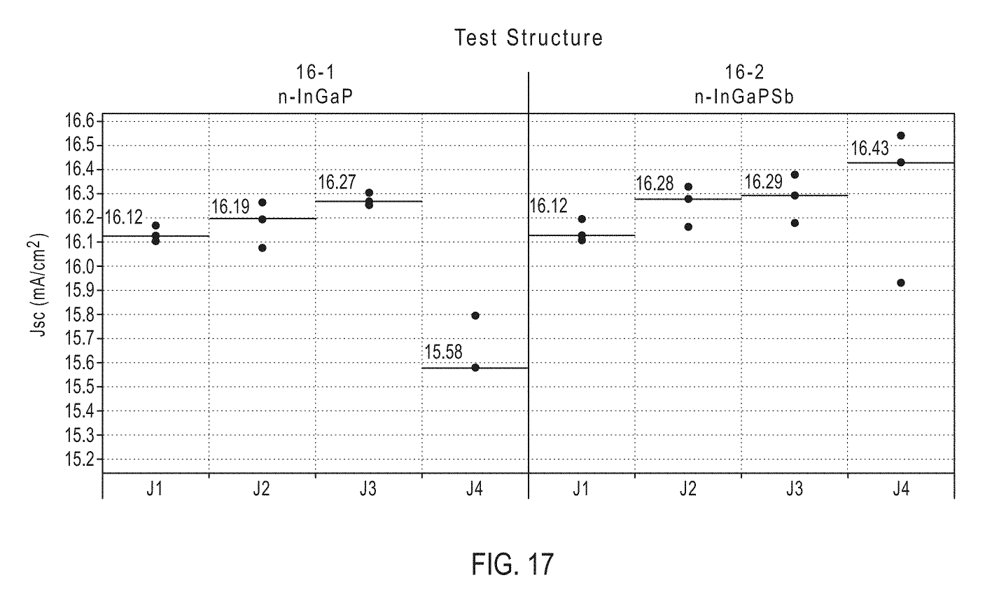

In FIG. 17, the Jsc for each of the subcells of the test structures 16-1 (n-InGaP nucleation layer) and 16-2 (n-InGaPSb nucleation layer) are compared. J1 represents the top (Al,In)GaP subcell, J2 the (Al,In)GaAs subcell, J3 the GaInNAsSb subcell and J4 the active p-Ge substrate. As shown in FIG. 17, the Jsc for each of subcells J1, J2, and J3 for test structures 16-1 and 16-2 are comparable; however, the Jsc of the active p-Ge substrate is significantly higher for the device having a n-InGaPSb nucleation layer compared to an n-InGaP nucleation layer, without antimony Sb.

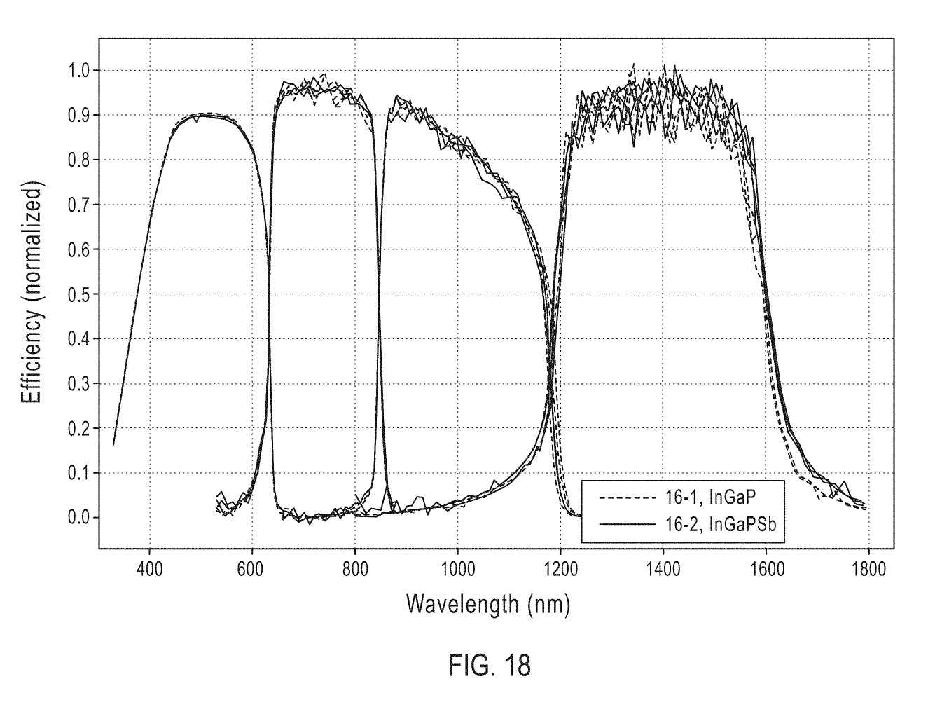

FIG. 18 shows the normalized wavelength-dependent efficiency for each of the subcells of test structures 16-1 (with an n-InGaP nucleation layer) and test structure 16-2 (with an n-InGaPSb nucleation layer). The efficiency in FIG. 18 is a LIV top cell current limited measurement that results from a spectral mismatch of the bandgap with the AM0 spectrum. The efficiency for the structure containing a InGaPSb nucleation layer would be higher if the 4J solar cell was bottom cell current limited under the AM0 spectrum. The external quantum efficiency is used to quantify the current per junction and the LIV voltage is the most accurate parameter to measure.

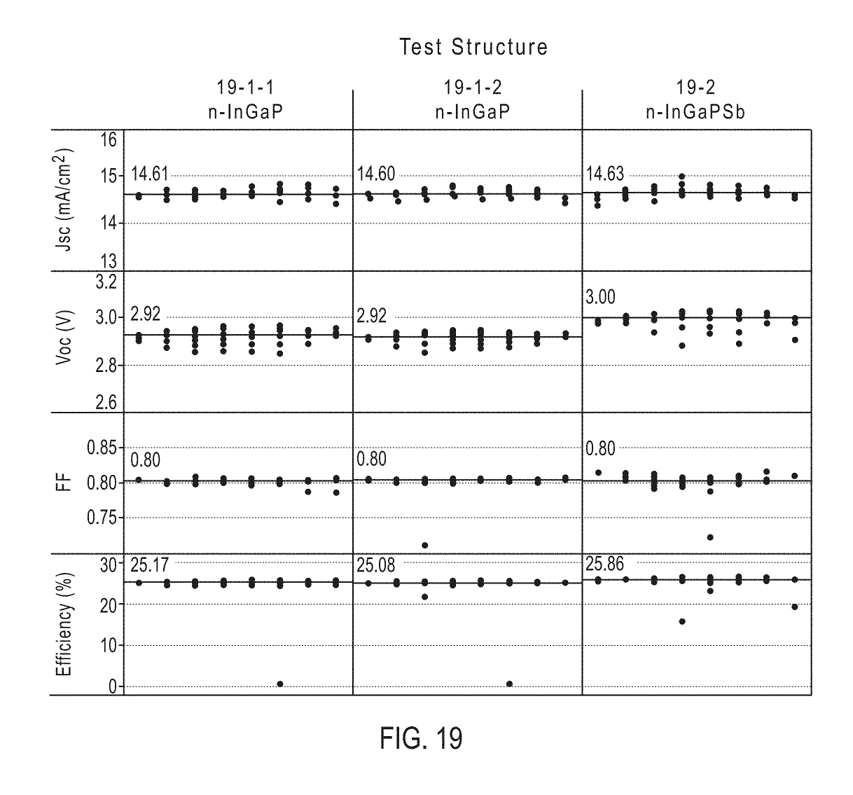

FIG. 19 shows, the Jsc, Voc, FF, and efficiency of a multijunction photovoltaic cell having the structure of FIG. 15 and having either an n-InGaP or an n-InGaPSb nucleation layer. The devices were subjected to an RTA thermal treatment at a temperature of 765° C. for 20 seconds after epitaxial growth of all layers was completed. As shown in FIG. 19, the Jsc, Voc, FF, and efficiency for the devices having either the n-InGaP (test structures 19-1-1 and 19-1-2) or the n-InGaPSb (test structure 19-2) nucleation layer were comparable.

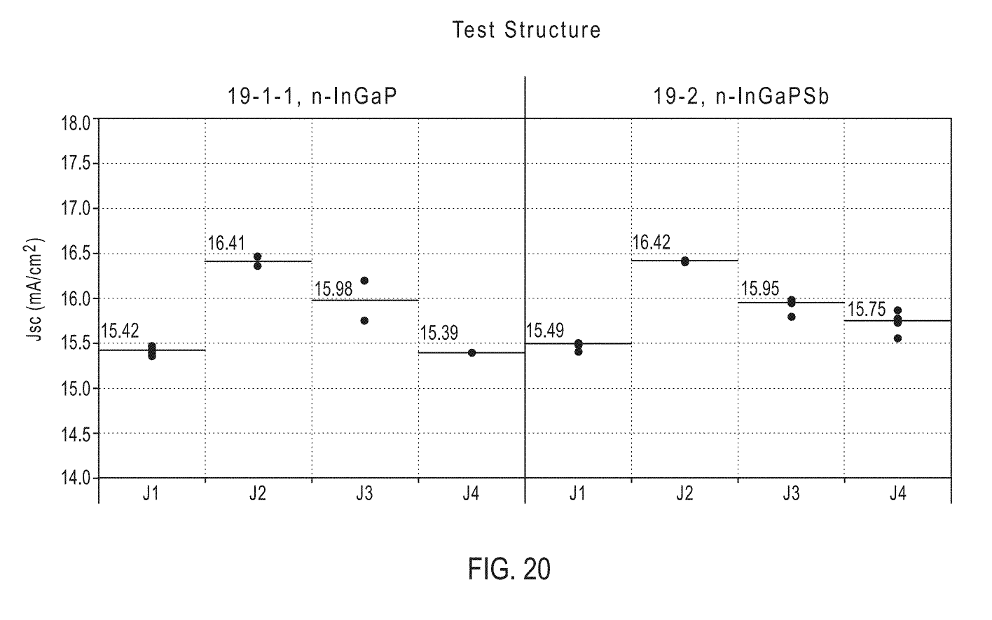

FIG. 20 shows the Jsc for each of the subcells of test structures 19-1-1 (with an n-InGaP nucleation layer) and 19-2 (with an n-InGaPSb nucleation layer). The Jsc for each of the respective layers J1-J2-J3 is comparable whether the nucleation layer is n-InGaP or n-InGaPSb; however, even for a very extreme thermal dose post-growth (765° C. for 20 seconds) the Jsc for the bottom J4 subcell with an n-InGaPSb nucleation layer was 0.4 mA/cm² (test structure 19-2) higher than that for the J4 subcell without Sb in the nucleation layer (test structure 19-1-1). An increase in the Jsc for the bottom subcell can translate into an improvement in efficiency of about 1.2%.

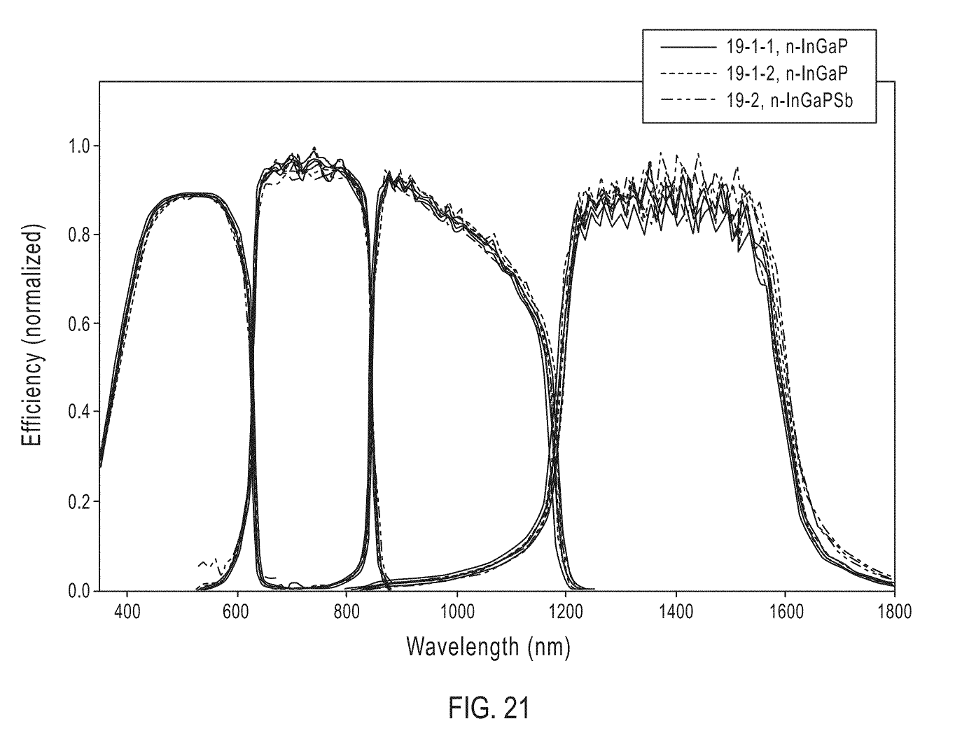

FIG. 21 shows the normalized wavelength-dependent efficiency for each of the subcells of test structures 19-1-1 and 19-1-2 (with an n-InGaP nucleation layer) and test structure 19-2 (with an n-InGaPSb nucleation layer). Multiplying the efficiency curves in FIG. 21 by the AM0 spectral intensity and integrating over the corresponding wavelength range for each subcell provides an external quantum efficiency (EQE), which is shown in FIG. 20. The EQE current is essentially a quantification of the efficiency curves shown in FIG. 21.

Test structures 21 were 4J photovoltaic cells having the structure of FIG. 15, but rather than being subjected to an RTA post-epitaxial growth, the bottom cell structure was exposed to the thermal load during the growth of the rest of the multijunction solar cell of about 620° C. during 3 hours. For example, for test structures 21, a nucleation layer comprising either n-InGaP (test structures 21-1-1 and 21-1-2) or n-InGaPSb (test structures 21-2-1 and 21-2-2) was grown on a p-Ge substrate (J1), and a GaInNAsSb dilute nitride subcell (J2) was grown as the second junction on top of the nucleation layer, and the (Al,In)GaAs (J3) and (Al,In)GaP (J4) subcells were grown overlying the dilute nitride subcell.

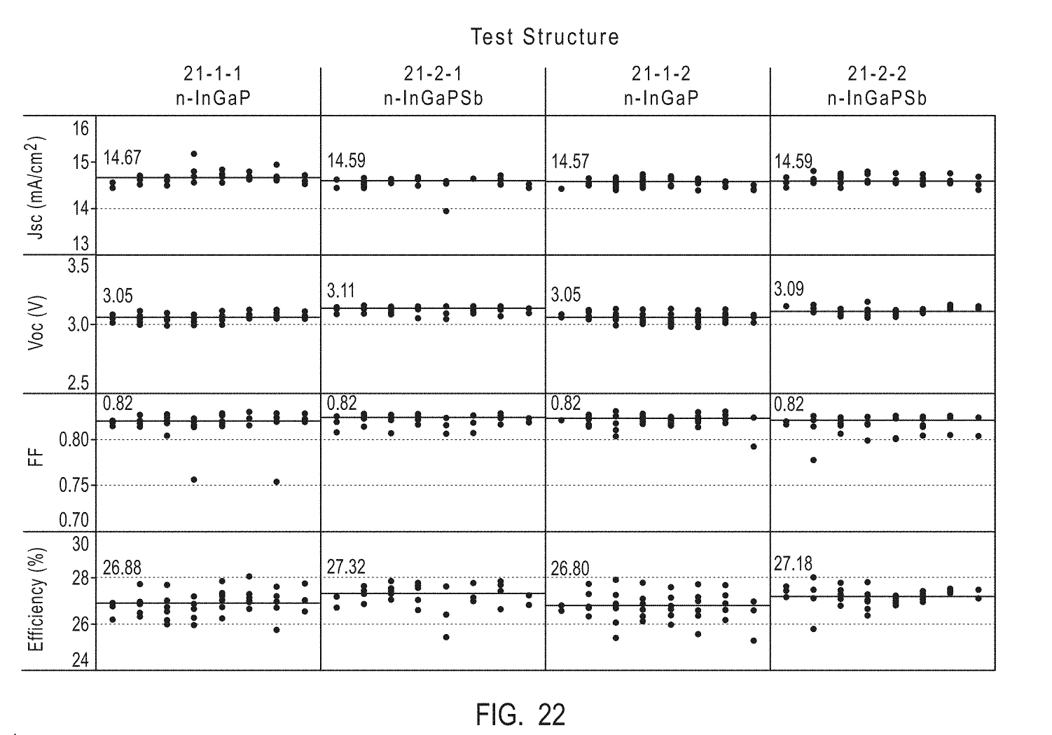

The Jsc, Voc, FF, and efficiency for test structures 21 are shown in FIG. 22. The efficiencies for the devices having an n-InGaPSb nucleation layer were significantly higher than for the devices having an n-InGaP nucleation layer.

FIG. 23 shows the Jsc for each of the subcells of test structures 21-1-1 and 21-1-2 (with an n-InGaP nucleation layer) and test structures 21-2-1 and 21-2-2 (with an n-InGaPSb nucleation layer). The Jsc for the p-Ge subcell (J4) was significantly greater for devices having an n-InGaPSb nucleation layer (test structure 21-2-1 and 21-2-2) compared to the Jsc for devices showing an n-InGaP nucleation layer (test structures 21-1-1 and 21-1-2).

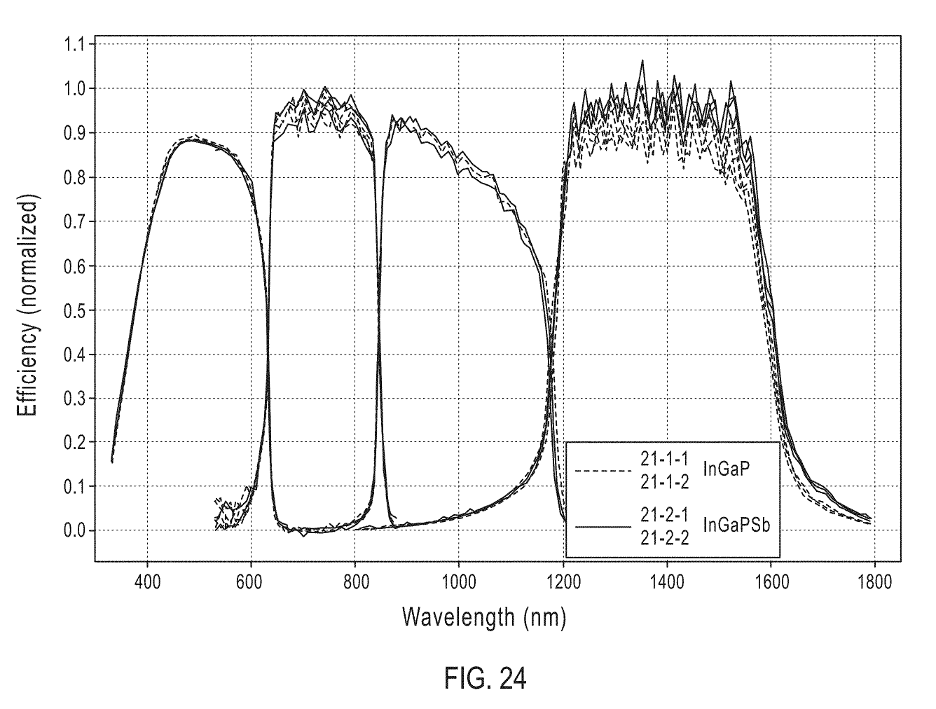

FIG. 24 shows the normalized wavelength-dependent efficiency for each of the subcells of test structures 21-1-1 and 21-1-2 (with an n-InGaP nucleation layer) and of test structures 21-2-1 and 21-2-2 (with an n-InGaPSb nucleation layer).

Based on these tests, the quantum efficiency of solar cells incorporating a (Al)InGaPSb, (Al)InGaPBi, or (Al)InGaPSbBi nucleation layer is higher than that of solar cells having a nucleation layer without Sb and/or Bi such as InGaP, especially at shorter wavelengths where the emitter response has a larger contribution to the overall efficiency. For multijunction solar cells having more than four (4) junctions, the bottom subcell will have a narrow wavelength absorption range due to the low bandgap of about 1 eV for the overlying J2 subcell; however, the increased efficiency will still be significant.

The embodiment illustrated in FIG. 15 was tested for performance characteristics and compared to an equivalent 4J device without antimony in the nucleation layer. The results are presented in FIGS. 16, 19, and 22 and are summarized in Table 4. Fifty-five individual 1-cm×1-cm photovoltaic cells on a 4-inch wafer were measured for each test structure. Device performance was measured at AM0. The measurements are plotted according to the position of each cell along the y-dimension of the wafer.

TABLE 4
Effects of antimony in the nucleation layer on 4J performance, with and without thermal treatment

| Test structure | 16-1 | 16-2 | 19-1-1 | 19-1-2 | 19-2 | 21-1-1 | 21-1-2 | 21-2-1 | 21-2-2 |
|---|---|---|---|---|---|---|---|---|---|
| Nucleation layer | InGaP | InGaPSb | InGaP | InGaP | InGaPSb | InGaP | InGaP | InGaPSb | InGaPSb |
| Application of | No | No | RTA | RTA | RTA | No | No | No | No |
| post thermal | | | 620° C., 20 s | 620° C., 20 s | 620° C., 20 s | | | | |
| treatment | | | | | | | | | |
| Voc (V) | 3.06 | 3.10 | 2.92 | 2.92 | 3.00 | 3.05 | 3.05 | 3.11 | 3.09 |
| Fill Factor | 0.83 | 0.83 | 0.80 | 0.80 | 0.80 | 0.82 | 0.82 | 0.82 | 0.82 |
| Jsc (mA/cm²) | 15.26 | 15.30 | 14.61 | 14.60 | 14.63 | 14.67 | 14.57 | 14.59 | 14.59 |
| Efficiency (%) | 28.45 | 28.92 | 25.17 | 25.08 | 25.86 | 26.88 | 27.18 | 27.32 | 27.18 |

For test structures 19-1-1, 19-1-2, and 19-2, an additional thermal treatment was applied via rapid thermal annealing (RTA) after epitaxial growth was complete for each 4J device. An increase was observed in Jsc, Voc, FF and efficiency of the 4J photovoltaic cell when antimony was present in the nucleation layer whether thermal treatment was applied after the epitaxial growth, by RTA, or during the epitaxial growth of subcells J2, J3, and J4. FIGS. 17, 20 and 23 show the short circuit current density Jsc of each subcell within the test structures. The Jsc of the bottom subcell (J4) with an InGaPSb nucleation layer was higher than the corresponding test structures having an InGaP nucleation layer without Sb. This shows that the overall increase in 4J Jsc is due to the presence of antimony within the nucleation layer on the J4 subcell. FIGS. 18, 21 and 24 compare the efficiency of each subcell for 16-1 and 16-2, and 19-1-1, 19-1-2 and 19-2, and 21-1-1, 21-1-2, 21-2-1 and 21-2-2, respectively. Over a range of irradiance energies, the J4 efficiency is improved with the InGaPSb nucleation layer in structures 16-2, 19-2, 21-2-1 and 21-2-2.

Embodiments of the present invention include optoelectronic devices that can be fabricated using molecular beam epitaxy (MBE) and/or chemical vapor deposition (CVD). As the composition is varied within a dilute nitride such as the Ga₁₋ₓInₓN_{y}As_{1-y-z}Sb_{z} material system, the growth conditions need to be modified. For example, for (Al,In)GaAs, the growth temperature will increase as the fraction of Al increases and decrease as the fraction of In increases, in order to maintain the same material quality. Thus, as a composition of either the Ga₁₋ₓInₓN_{y}As_{1-y-z}Sb_{z} material or the other subcells of the multijunction photovoltaic cell is changed, the growth temperature as well as other growth conditions can be adjusted accordingly. The thermal dose applied to dilute nitrides after MBE or CVD growth, which is controlled by the intensity of heat applied for a given duration of time (e.g., application of a temperature of 600° C. to 900° C. for a duration of between 10 seconds to 10 hours; see Table 2), also affects the relationship between band gap and composition. This thermal annealing step may be performed in an atmosphere that includes air, nitrogen, arsenic, arsine, phosphorus, phosphine, hydrogen, forming gas, oxygen, helium and any combination of the preceding materials. In general, the band gap and doping profiles change as thermal annealing parameters change. The presence of dopants further complicates determination of the optimal combination of elements, growth parameters and thermal annealing conditions that will produce suitable high efficiency subcells having a specific band gap and vertical distribution of dopants.

In certain embodiments provided by the present disclosure, a plurality of layers is deposited on a substrate in a first materials deposition chamber. The plurality of layers may include etch stop layers, release layers (i.e., layers designed to release the semiconductor layers from the substrate when a specific process sequence, such as chemical etching, is applied), protective layers, contact layers such as lateral conduction layers, buffer layers, or other semiconductor layers. In certain embodiments, the sequence of layers deposited is buffer layer(s), then release layer(s), and then lateral conduction or contact layer(s). Next the substrate is transferred to a second materials deposition chamber where one or more subcells are deposited on top of the existing semiconductor layers. The substrate may then be transferred to either the first materials deposition chamber or to a third materials deposition chamber for deposition of one or more subcells and then deposition of one or more contact layers. Tunnel junctions are also formed between the subcells.

It can be appreciated that nucleation layers containing Sb and/or Bi can be used to modify, attenuate, or minimize diffusion of elements contained in overlying layers into an underlying layer. Diffusion of elements from an overlying semiconductor layer into a Ge substrate is an example. A nucleation layer containing Si and/or Bi can render a semiconductor device more robust to thermal processing and in particular high temperature thermal processing. A nucleation layer containing Sb and/or Bi can improve the performance of semiconductor devices exposed to high temperatures during processing.

Multijunction photovoltaic cells incorporating Sb and/or Bi-containing nucleation layers can exhibit high efficiency. The Sb and/or Bi-containing nucleation layer can improve the performance of semiconductor devices such as multijunction photovoltaic cells exposed to high temperatures during processing and/or annealing such as multijunction photovoltaic cells incorporating dilute nitride subcells such as GaInNAsSb subcells. To obtain high efficiency, GaInNAsSb alloys must be exposed to high temperatures. For example, a photovoltaic cell containing a dilute nitride subcell can be subjected to one or more thermal annealing treatments after growth. For example, a thermal annealing treatment can include the application of a temperature of 400° C. to 1000° C. for between 10 seconds and 10 hours. Thermal annealing may be performed in an atmosphere that includes air, nitrogen, arsenic, arsine, phosphorus, phosphine, hydrogen, forming gas, oxygen, helium and any combination of the preceding materials. In certain embodiments, a stack of subcells and associated tunnel junctions may be annealed prior to fabrication of additional overlying subcells.

Multijunction photovoltaic cells incorporating dilute nitrides such as GaInNAsSb/Bi and a Sb and/or Bi containing nucleation layer exhibit high efficiency. The efficiency of GaInNAsSb subcells is shown in FIG. 25. Ga₁₋ₓInₓN_{y}As_{1-y-z}Sb_{z} subcells provided by the present disclosure are fabricated to provide a high internal quantum efficiency. Factors that contribute to providing a high internal quantum efficiency Ga₁₋ₓInₓN_{y}As_{1-y-z}Sb_{z} subcells include, for example, the band gaps of the individual subcells, which in turn depends on the semiconductor composition of the subcells, doping levels and doping profiles, thicknesses of the subcells, quality of lattice matching, defect densities, growth conditions, annealing temperatures and profiles, and impurity levels.

Various metrics can be used to characterize the quality of a GaInNAsSb subcell including, for example, the Eg/q-Voc, the internal quantum efficiency over a range of irradiance energies, the open circuit voltage Voc and the short circuit current density Jsc. The open circuit voltage Voc and short circuit current Jsc can be measured on subcells having a Ga₁₋ₓInₓN_{y}As_{1-y-z}Sb_{z} base layer that is 2 μm thick or other thickness such as, for example, a thickness from 1 μm to 4 μm. Those skilled in the art would understand how to extrapolate the open circuit voltage Voc and short circuit current Jsc measured for a subcell having a particular Ga₁₋ₓInₓN_{y}As_{1-y-z}Sb_{z} base thickness to other thicknesses.

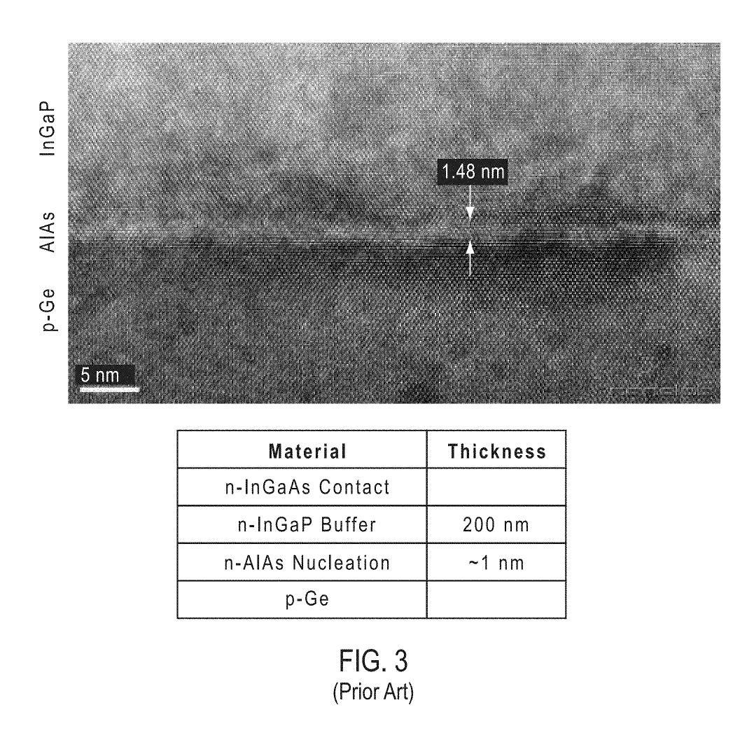

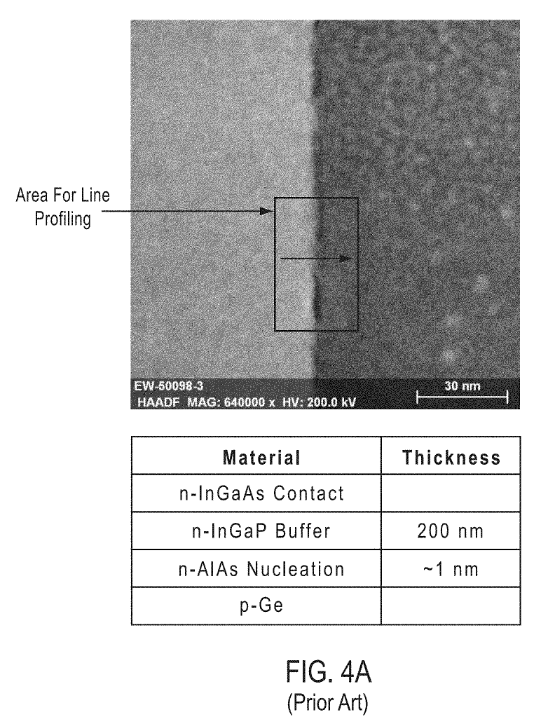

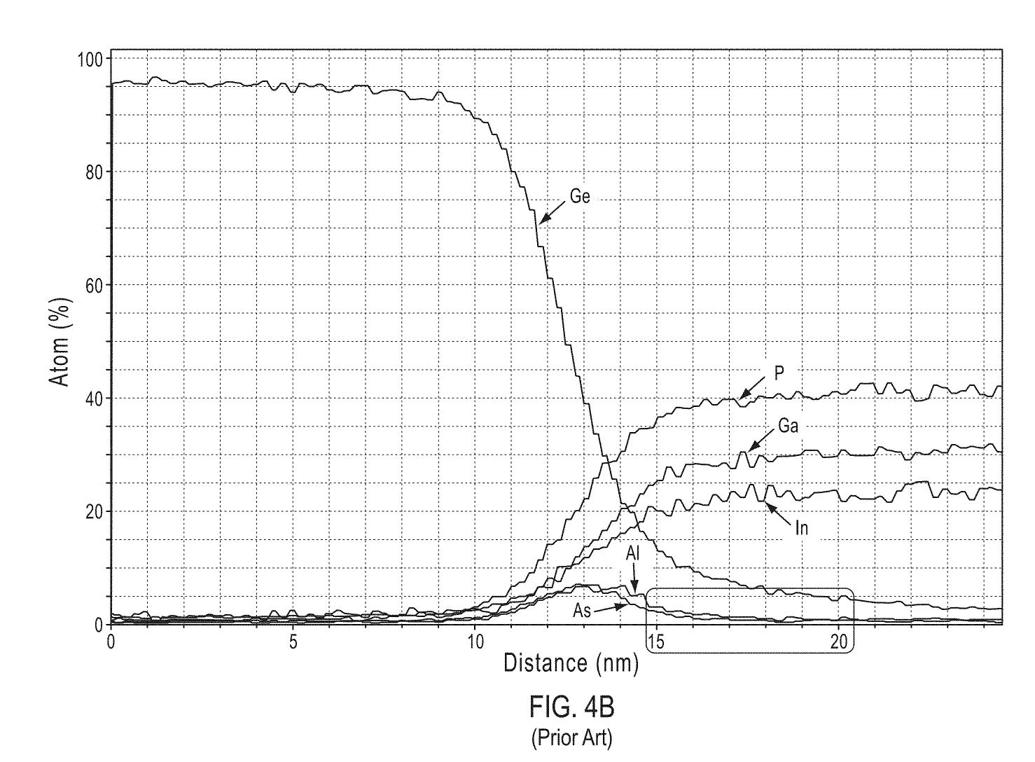

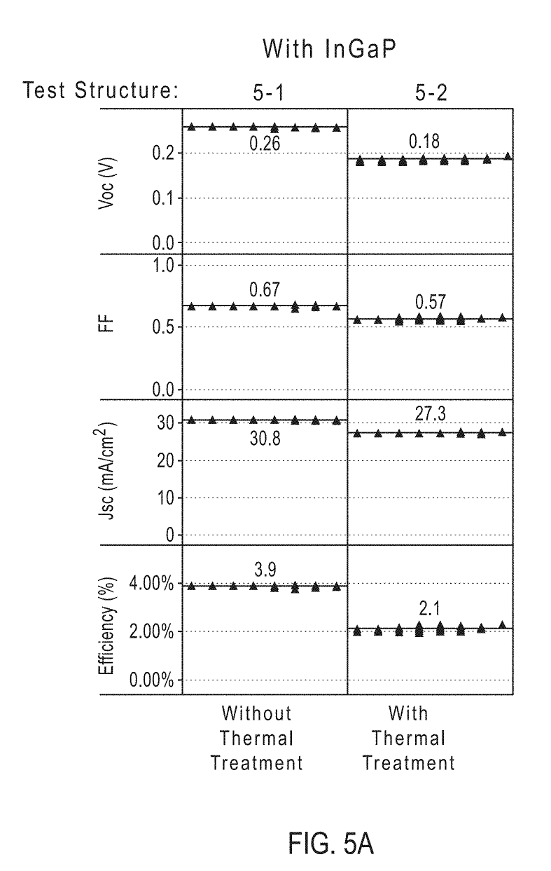

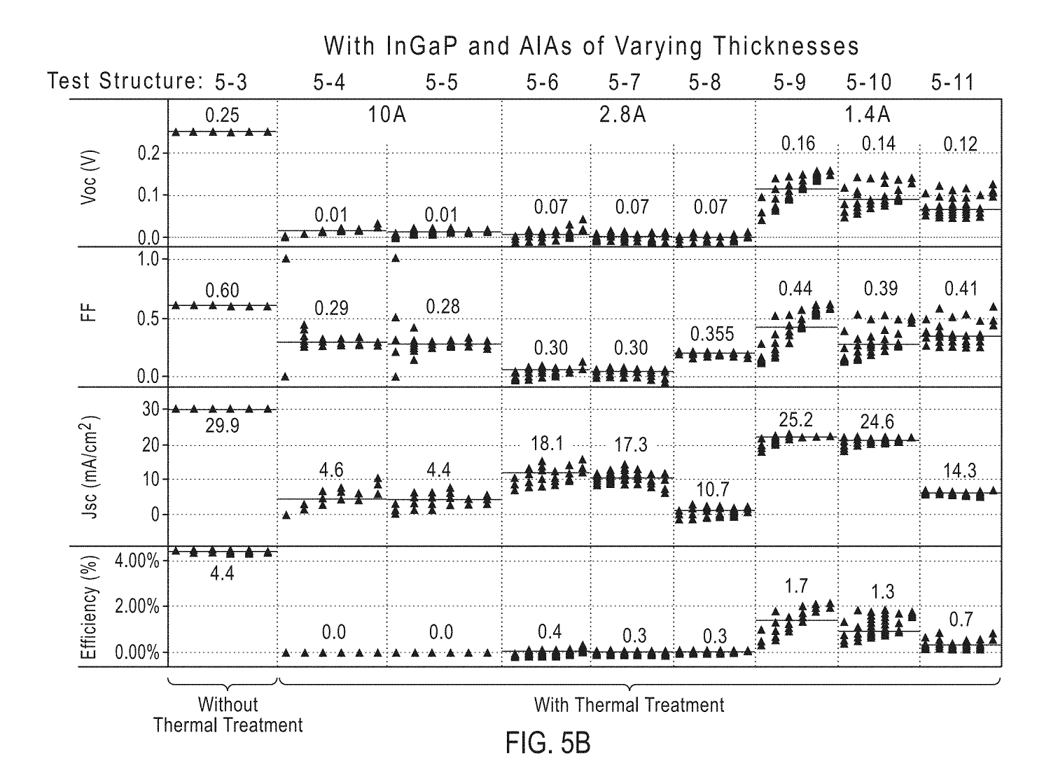

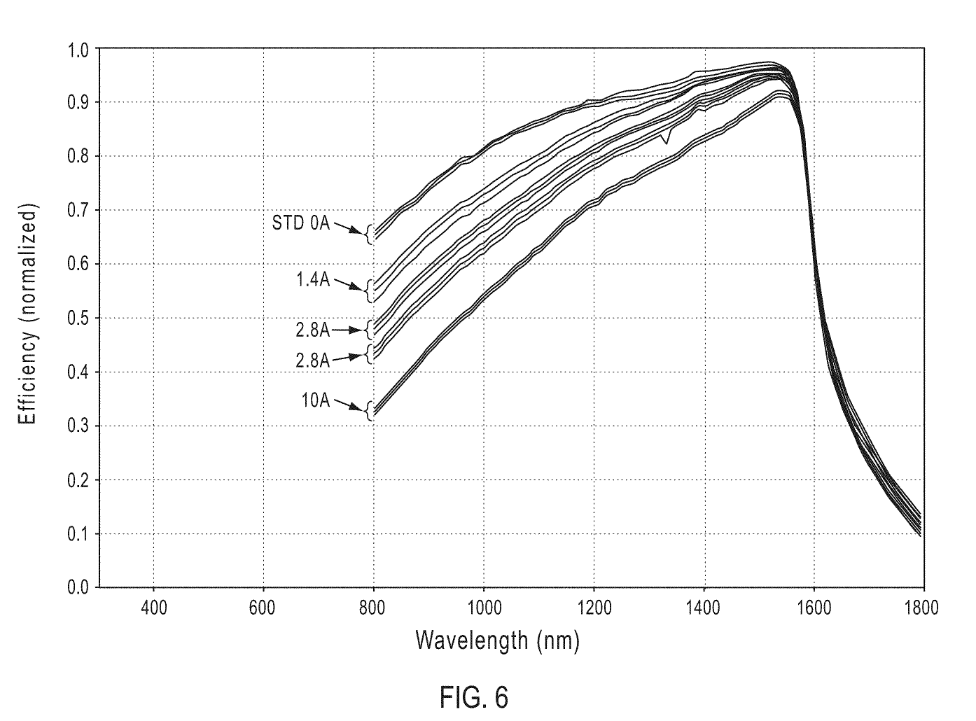

The quality of a Ga₁₋ₓInₓN_{y}As_{1-y-z}Sb_{z} subcell can be reflected by a curve of the internal quantum efficiency as a function of irradiance wavelength or irradiance energy. In general, a high quality Ga₁₋ₓInₓN_{y}As_{1-y-z}Sb_{z} subcell exhibits an internal quantum efficiency (IQE) of at least 60%, at least 70% or at least 80% over a wide range of irradiance wavelengths. FIG. 3 shows the dependence of the internal quantum efficiency as a function of irradiance wavelength/energy for Ga₁₋ₓInₓN_{y}As_{1-y-z}Sb_{z} subcells having band gaps from about 0.82 eV to about 1.24 eV.

The Ga₁₋ₓInₓN_{y}As_{1-y-z}Sb_{z} subcells measured in FIG. 25 exhibit high internal quantum efficiencies greater than 60%, greater than 70%, or greater than 80% over a broad irradiance wavelength range. The high internal quantum efficiency of these Ga₁₋ₓInₓN_{y}As_{1-y-z}Sb_{z} subcells over a broad range of irradiance wavelengths/energies is indicative of the high quality of the semiconductor material forming the Ga₁₋ₓInₓN_{y}As_{1-y-z}Sb_{z} subcell.

As shown in FIG. 25, the range of irradiance wavelengths over which a particular Ga₁₋ₓInₓN_{y}As_{1-y-z}Sb_{z} subcell exhibits a high internal quantum efficiency is bounded by the band gap of a particular Ga₁₋ₓInₓN_{y}As_{1-y-z}Sb_{z} subcell. Measurements are not extended to wavelengths below 900 nm because in a practical photovoltaic cell, a Ge subcell can be used to capture and convert radiation at the shorter wavelengths. The internal quantum efficiencies in FIG. 25 were measured at an irradiance of 1 sun (1,000 W/m²) with the AM1.5D spectrum at a junction temperature of 25° C., for a GaInNAsSb subcell thickness of 2μm. One skilled in the art will understand how to extrapolate the measured internal quantum efficiencies to other irradiance wavelengths/energies, subcell thicknesses, and temperatures. The internal quantum efficiency was measured by scanning the spectrum of a calibrated source and measuring the current generated by the photovoltaic cell. A GaInNAsSb subcell can include a GaInNAsSb subcell base, an emitter, a back surface field and a front surface field.

The Ga₁₋ₓInₓN_{y}As_{1-y-z}Sb_{z} subcells exhibited an internal quantum efficiency as follows:
an internal quantum efficiency of at least 70% at an irradiance energy from 1.38 eV to 1.30 eV, and an internal quantum efficiency of at least 80% at an irradiance energy from 1.38 eV to 1.30 eV;
an internal quantum efficiency of at least 70% at an irradiance energy from 1.38 eV to 1.18 eV, and an internal quantum efficiency of at least 80% at an irradiance energy from 1.38 eV to 1.30 eV;
an internal quantum efficiency of at least 70% at an irradiance energy from 1.38 eV to 1.10 eV, and an internal quantum efficiency of at least 80% at an irradiance energy from 1.38 eV to 1.18 eV;
an internal quantum efficiency of at least 70% at an irradiance energy from 1.38 eV to 1.03 eV, and an internal quantum efficiency of at least 80% at an irradiance energy from 1.38 eV to 1.15 eV;
an internal quantum efficiency of at least 70% at an irradiance energy from 1.38 eV to 0.99 eV, and an internal quantum efficiency of at least 80% at an irradiance energy from 1.38 eV to 1.15 eV; or
an internal quantum efficiency of at least 60% at an irradiance energy from 1.38 eV to 0.92 eV, an internal quantum efficiency of at least 70% at an irradiance energy from 1.38 eV to 1.03 eV, and an internal quantum efficiency of at least 80% at an irradiance energy from 1.38 eV to 1.15 eV.
wherein the internal quantum efficiency was measured at a junction temperature of 25° C.

Ga₁₋ₓInₓN_{y}As_{1-y-z}Sb_{z} subcells having a band gap between 1.18 eV and 1.24 eV, exhibited an internal quantum efficiency an internal quantum efficiency of at least 70% at an irradiance energy from 1.38 eV to 1.30 eV, and an internal quantum efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.10 eV and 1.14 eV, exhibited an internal quantum efficiency of at least 70% at an irradiance energy from 1.38 eV to 1.18 eV, and an internal quantum efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.04 eV and 1.06 eV, exhibited an internal quantum efficiency of at least 70% at an irradiance energy from 1.38 eV to 1.10 eV, and an internal quantum efficiency of at least 80% at an irradiance energy from 1.38 eV to 1.18 eV, measured at a junction temperature of 25° C.

Ga₁₋ₓInₓN_{y}As_{1-y-z}Sb_{z} subcells having a band gap between 0.99 eV and 1.01 eV, exhibited an internal quantum efficiency of at least 70% at an irradiance energy from 1.38 eV to 1.03 eV, and an internal quantum efficiency of at least 80% at an irradiance energy from 1.38 eV to 1.15 eV, measured at a junction temperature of 25° C.

Ga₁₋ₓInₓN_{y}As_{1-y-z}Sb_{z} subcells having a band gap between 0.90 eV and 0.98 eV, exhibited an internal quantum efficiency of at least 70% at an irradiance energy from 1.38 eV to 0.99 eV, and an internal quantum efficiency of at least 80% at an irradiance energy from 1.38 eV to 1.15 eV, measured at a junction temperature of 25° C.

Ga₁₋ₓInₓN_{y}As_{1-y-z}Sb_{z} subcells having a band gap between 0.80 eV and 0.86 eV, exhibited an internal quantum efficiency of at least 60% at an irradiance energy from 1.38 eV to 0.92 eV, an internal quantum efficiency of at least 70% at an irradiance energy from 1.38 eV to 1.03 eV, and an internal quantum efficiency of at least 80% at an irradiance energy from 1.38 eV to 1.15 eV, measured at a junction temperature of 25° C.

The Ga₁₋ₓInₓN_{y}As_{1-y-z}Sb_{z} subcells also exhibited an internal quantum efficiency as follows:
an internal quantum efficiency of at least 70% at an irradiance energy from 1.38 eV to 1.27 eV, and an internal quantum efficiency of at least 80% at an irradiance energy from 1.38 eV to 1.30 eV;
an internal quantum efficiency of at least 70% at an irradiance energy from 1.38 eV to 1.18 eV, and an internal quantum efficiency of at least 80% at an irradiance energy from 1.38 eV to 1.30 eV;
an internal quantum efficiency of at least 70% at an irradiance energy from 1.38 eV to 1.10 eV, and an internal quantum efficiency of at least 80% at an irradiance energy from 1.38 eV to 1.18 eV;
an internal quantum efficiency of at least 70% at an irradiance energy from 1.38 eV to 1.03 eV, and an internal quantum efficiency of at least 80% at an irradiance energy from 1.38 eV to 1.13 eV; or
an internal quantum efficiency of at least 60% at an irradiance energy from 1.38 eV to 0.92 eV, an internal quantum efficiency of at least 70% at an irradiance energy from 1.38 eV to 1.03 eV, and an internal quantum efficiency of at least 80% at an irradiance energy from 1.38 eV to 1.08 eV; wherein the internal quantum efficiency is measured at a junction temperature of 25° C.

Ga₁₋ₓInₓN_{y}As_{1-y-z}Sb_{z} subcells having a band gap between 1.18 eV and 1.24 eV, exhibited an internal quantum efficiency of at least 70% at an irradiance energy from 1.38 eV to 1.27 eV, and an internal quantum efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.10 eV and 1.14 eV, exhibited an internal quantum efficiency of at least 70% at an irradiance energy from 1.38 eV to 1.18 eV, and an internal quantum efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.04 eV and 1.06 eV, exhibited an internal quantum efficiency of at least 70% at an irradiance energy from 1.38 eV to 1.10 eV, and an internal quantum efficiency of at least 80% at an irradiance energy from 1.38 eV to 1.18 eV, measured at a junction temperature of 25° C.

Ga₁₋ₓInₓN_{y}As_{1-y-z}Sb_{z} subcells having a band gap between 0.94 eV and 0.98 eV, exhibited an internal quantum efficiency of at least 70% at an irradiance energy from 1.38 eV to 1.03 eV, and an internal quantum efficiency of at least 80% at an irradiance energy from 1.38 eV to 1.13 eV, measured at a junction temperature of 25° C.

Ga₁₋ₓInₓN_{y}As_{1-y-z}Sb_{z} subcells having a band gap between 0.80 eV and 0.90 eV, exhibited an internal quantum efficiency of at least 60% at an irradiance energy from 1.38 eV to 0.92 eV, an internal quantum efficiency of at least 70% at an irradiance energy from 1.38 eV to 1.03 eV, and an internal quantum efficiency of at least 80% at an irradiance energy from 1.38 eV to 1.08 eV, measured at a junction temperature of 25° C.

The Ga₁₋ₓInₓN_{y}As_{1-y-z}Sb_{z} subcells exhibited an Eg/q-Voc of at least 0.55 V, at least 0.60 V, or at least 0.65 V over each respective range of irradiance energies listed in the preceding paragraph. The Ga₁₋ₓInₓN_{y}As_{1-y-z}Sb_{z} subcells exhibited an Eg/q-Voc within the range of 0.55 V to 0.70 V over each respective range of irradiance energies listed in the preceding paragraphs.

A Ga₁₋ₓInₓN_{y}As_{1-y-z}Sb_{z} subcell can be characterized by a band gap of about 1.24 eV, an internal quantum efficiency greater than 70% at irradiance energies from about 1.27 eV to about 1.38 eV and an internal quantum efficiency greater than 80% at irradiance energies from about 1.33 eV to about 1.38 eV.

A Ga₁₋ₓInₓN_{y}As_{1-y-z}Sb_{z} subcell can be characterized by a band gap of about 1.14 eV, an internal quantum efficiency greater than 70% at irradiance energies from about 1.24 eV to about 1.38 eV and an internal quantum efficiency greater than 80% at irradiance energies from about 1.30 eV to about 1.38 eV.

A Ga₁₋ₓInₓN_{y}As_{1-y-z}Sb_{z} subcell can be characterized by a band gap of about 1.10 eV, an internal quantum efficiency greater than 70% at irradiance energies from about 1.18 eV to about 1.38 eV and an internal quantum efficiency greater than 80% at irradiance energies from about 1.30 eV to about 1.38 eV.

A Ga₁₋ₓInₓN_{y}As_{1-y-z}Sb_{z} subcell can be characterized by a band gap of about 1.05 eV, an internal quantum efficiency greater than 70% at irradiance energies from about 1.13 eV to about 1.38 eV and an internal quantum efficiency greater than 80% at irradiance energies from about 1.18 eV to about 1.38 eV.

A Ga₁₋ₓInₓN_{y}As_{1-y-z}Sb_{z} subcell can be characterized by a band gap of about 1.00 eV, an internal quantum efficiency greater than 70% at irradiance energies from about 1.08 eV to about 1.38 eV and an internal quantum efficiency greater than 80% at irradiance energies from about 1.13 eV to about 1.38 eV.

A Ga₁₋ₓInₓN_{y}As_{1-y-z}Sb_{z} subcell can be characterized by a band gap of about 0.96 eV, an internal quantum efficiency greater than 70% at irradiance energies from about 1.03 eV to about 1.38 eV and an internal quantum efficiency greater than 80% at irradiance energies from about 1.13 eV to about 1.38 eV.

A Ga₁₋ₓInₓN_{y}As_{1-y-z}Sb_{z} subcell can be characterized by a band gap of about 0.82 eV, an internal quantum efficiency greater than 70% at irradiance energies from about 0.99 eV to about 1.38 eV and an internal quantum efficiency greater than 80% at irradiance energies from about 1.13 eV to about 1.38 eV.

Further aspects of the invention include the following aspects individually or in any combination:

In an aspect of the invention, semiconductor devices comprise a substrate, wherein the substrate comprises GaAs, (Si,Sn)Ge or Si; and a nucleation layer overlying the substrate, wherein the nucleation layer comprises a III-V alloy, wherein the group V element comprises Sb, Bi, or a combination thereof.

In any of the preceding aspects of the invention, the substrate comprises Ga-doped Ge.

In any of the preceding aspects of the invention, the III-V alloy comprises (Al)InGaPSb/Bi.

In any of the preceding aspects of the invention, the nucleation layer is lattice matched to the substrate.

In any of the preceding aspects of the invention, the nucleation layer is n-doped and the substrate is p-doped.

In any of the preceding aspects of the invention, he III-V alloy comprises from 0.2% to 10% Sb, Bi, or a combination thereof, where % is based on the elemental content.

In any of the preceding aspects of the invention, the nucleation layer has a thickness from 0.01 nm to 1 nm.

In any of the preceding aspects of the invention, a region of the substrate within a range from 10 nm to 50 nm adjacent the nucleation layer comprises Sb or Bi.

In any of the preceding aspects of the invention, the semiconductor device further comprises at least one dilute nitride semiconductor layer overlying the nucleation layer, wherein the at least one dilute nitride semiconductor layer comprising at least one group III element comprises Al, Ga, In, or a combination of any of the foregoing; and at least one group V element comprising N, P, As, Sb, Bi, or a combination of any of the foregoing.

In any of the preceding aspects of the invention, the at least one dilute nitride semiconductor layer comprises GaInNAs, GaInNAsSb, GaInNAsBi, GaInNAsSbBi, GaNAs, GaNAsSb, GaNAsBi, or GaNAsSbBi.

In any of the preceding aspects of the invention, the semiconductor device comprises a multijunction photovoltaic cell.

In any of the preceding aspects of the invention, the multijunction solar cell exhibits an efficiency greater than 30% measured with a 1 sun AM0 standard space spectrum at a junction temperature of 25° C.

In any of the preceding aspects of the invention, the multijunction photovoltaic cell comprises at least one dilute nitride subcell overlying the nucleation layer.

In any of the preceding aspects of the invention, the substrate comprises Ga-doped germanium; the nucleation layer comprises (Al)InGaPSb, (Al)InGaPBi, or (Al)InGaPSbBi; and the at least one dilute nitride subcell comprises GaInNAsSb, GaInNAsBi, or GaInNAsSbBi.

In any of the preceding aspects of the invention, the semiconductor device further comprises a (Al,In)GaAs subcell overlying the at least one dilute nitride subcell; and a (Al,In)GaP subcell overlying the (Al,In)GaAs subcell.

In any of the preceding aspects of the invention, the at least one dilute nitride subcell exhibits a normalized quantum efficiency within the wavelength range from 800 nm to 1500 nm is greater than 0.8.

In any of the preceding aspects of the invention, the multijunction solar cell comprises at least two subcells and each of the at least two subcells is lattice matched to the substrate and to each of the other at least two subcells.

In any of the preceding aspects of the invention, the semiconductor device comprises a p-type substrate and an emitter layer at an interface between the nucleation layer and the p-type substrate, wherein the emitter layer comprises a group V element selected from P, Sb, Bi, or a combination of any of the foregoing.

In any of the preceding aspects of the invention, the semiconductor comprises a p-type substrate and diffusion of a p-type dopant into the p-type substrate is attenuated within the first 50 nm from the nucleation layer.

In any of the preceding aspects of the invention, a Ga concentration within a range of 50 nm to 200 nm from the interface with the nucleation layer is constant.

In any of the preceding aspects of the invention, the substrate comprises germanium Ge and the substrate comprises antimony Sb in a region adjacent the nucleation layer.

In any of the preceding aspects of the invention, the III-V alloy comprises (Al)InGaPSb/Bi.

In any of the preceding aspects of the invention, the semiconductor device was exposed to a temperature from 600° C. to 900° C. for a duration from 5 seconds to 5 hours.

In an aspect of the invention, solar energy power systems comprise at least one multijunction photovoltaic cell according to any of the preceding aspects of the invention.

In an aspect of the invention, methods of fabricating a semiconductor device, comprise growing a nucleation layer on a substrate, wherein the nucleation layer comprises a III-V alloy, wherein the group V element comprises Sb, Bi, or a combination thereof; and growing at least one semiconductor layer on the nucleation layer.

In any of the preceding aspects of the invention, the substrate comprises Ge; and the III-V alloy comprises (Al)InGaPSb/Bi.

In any of the preceding aspects of the invention, the at least one semiconductor layer comprises a dilute nitride alloy.

According to the present invention, semiconductor devices comprise semiconductor devices fabricated using methods according to any of the preceding aspects.

It should be noted that there are alternative ways of implementing the embodiments disclosed herein. Accordingly, the present embodiments are to be considered as illustrative and not restrictive. Furthermore, the claims are not to be limited to the details given herein, and are entitled their full scope and equivalents thereof.

What is claimed is:

1. A semiconductor device, comprising:
a substrate, wherein the substrate comprises GaAs, (Si,Sn)Ge or Si; and
a nucleation layer overlying the substrate, wherein the nucleation layer comprises a III-V alloy, wherein the group V element comprises Sb, Bi, or a combination thereof.

2. The semiconductor device of claim 1, wherein the substrate comprises Ga-doped Ge.

3. The semiconductor device of claim 1, wherein the III-V alloy comprises (Al)InGaPSb/Bi.

4. The semiconductor device of claim 1, wherein the nucleation layer is lattice matched to the substrate.

5. The semiconductor device of claim 1, wherein the nucleation layer is n-doped and the substrate is p-doped.

6. The semiconductor device of claim 1, wherein the III-V alloy comprises from 0.2% to 10% Sb, Bi, or a combination thereof, where % is based on elemental content.

7. The semiconductor device of claim 1, wherein a region of the substrate within a range from 10 nm to 50 nm adjacent the nucleation layer comprises Sb or Bi.

8. The semiconductor device of claim 1, further comprising at least one dilute nitride semiconductor layer overlying the nucleation layer, wherein the at least one dilute nitride semiconductor layer comprises:
at least one group III element comprising Al, Ga, In, or a combination of any of the foregoing; and
at least one group V element comprising N, P, As, Sb, Bi, or a combination of any of the foregoing.

9. The semiconductor device of claim 8, wherein the at least one dilute nitride semiconductor layer comprises GaInNAs, GaInNAsSb, GaInNAsBi, GaInNAsSbBi, GaNAs, GaNAsSb, GaNAsBi, or GaNAsSbBi.

10. The semiconductor device of claim 1, wherein the semiconductor device comprises a multijunction photovoltaic cell.

11. The semiconductor device of claim 10, wherein the multijunction solar cell exhibits an efficiency greater than 30%, measured with a 1 sun AM0 standard space spectrum at a junction temperature of 25° C.

12. The semiconductor device of claim 11, wherein,
the substrate comprises Ga-doped germanium;
the nucleation layer comprises (Al)InGaPSb, (Al)InGaPBi, or (Al)InGaPSbBi; and
the at least one dilute nitride subcell comprises GaInNAsSb, GaInNAsBi, or GaInNAsSbBi.

13. The semiconductor device of claim 11, further comprising:
a (Al,In)GaAs subcell overlying the at least one dilute nitride subcell; and
a (Al,In)GaP subcell overlying the (Al,In)GaAs subcell.

14. The semiconductor device of claim 1, comprising an emitter layer at an interface between the nucleation layer and the substrate, wherein,
the substrate is a p-type substrate; and
the emitter layer comprises a group V element selected from P, Sb, Bi, or a combination of any of the foregoing.

15. The semiconductor device of claim 1, wherein,
the substrate is a p-type substrate; and
diffusion of a p-type dopant into the p-type substrate is attenuated within the first 50 nm from the nucleation layer.

16. The semiconductor device of claim 1, wherein a Ga concentration within a range of 50 nm to 200 nm from the interface with the nucleation layer is constant.

17. The semiconductor device of claim 1, wherein,
the substrate comprises germanium Ge; and
the substrate comprises antimony Sb in a region adjacent the nucleation layer.

18. The semiconductor device of claim 1, wherein the III-V alloy comprises (Al)InGaPSb/Bi.

19. A solar energy power system comprising at least one multijunction photovoltaic cell of claim 10.

20. A method of fabricating a semiconductor device, comprising:
growing a nucleation layer on a substrate, wherein the nucleation layer comprises a III-V alloy, wherein the group V element comprises Sb, Bi, or a combination thereof; and
growing at least one semiconductor layer on the nucleation layer.

21. The method of claim 20, wherein,
the substrate comprises Ge; and
the III-V alloy comprises (Al)InGaPSb/Bi.

22. The method of claim 20, wherein the at least one semiconductor layer comprises a dilute nitride alloy.

23. A semiconductor device fabricated using the method of claim 20.
